(19) United States
(12) Patent Application Publication
(10) Pub. No.: US 2021/0307181 A1
(43) Pub. Date: Sep. 30, 2021

(54) FOLDABLE DEVICE AND AN ELECTRONIC DEVICE

(71) Applicant: SHENZHEN ROYOLE TECHNOLOGIES CO., LTD, Shenzhen (CN)

(72) Inventors: Zhuping Hong, Shenzhen (CN); Wenjun Liu, Shenzhen (CN); Shuai Su, Shenzhen (CN); Xiaofei Fan, Shenzhen (CN); Songya Chen, Shenzhen (CN)

(21) Appl. No.: 17/210,971

(22) Filed: Mar. 24, 2021

(30) Foreign Application Priority Data
Mar. 25, 2020 (CN) 202010221982.2

(51) Int. Cl. H05K 5/00; G06F 1/16

(52) U.S. Cl. CPC H05K 5/0026; G06F 1/1652; G06F 1/1681

(57) ABSTRACT

A foldable device including a bendable mechanism, a connection mechanism, and a shielding mechanism is provided. The connection mechanism is coupled to the bendable mechanism, and is slidable relative to the bendable mechanism as the bendable mechanism is folded. The shielding mechanism is arranged on an inner side of the bendable mechanism. The shielding mechanism is coupled to the connection mechanism. When the bendable mechanism is folded, the connection mechanism is capable of driving the shielding mechanism to slide relative to the bendable mechanism. Since the shielding mechanism is arranged on the inner side of the bendable mechanism, and is folded or unfolded together with the bendable mechanism, thus preventing dust and other impurities from entering the foldable device from the inner side. An electronic device including the foldable device is further provided.

### CROSS-REFERENCE TO RELATED APPLICATION

The present disclosure claims priority to and the benefit of Chinese Application Patent No. 202010221982.2, filed on Mar. 25, 2020, the entire disclosure of which is hereby incorporated by reference in its entirety.

### TECHNICAL FIELD

The present disclosure relates to the field of support of a flexible member, and more particularly to a foldable device for supporting the flexible member and an electronic device including the foldable device.

### BACKGROUND

With the development of displays, flexible and ultra-thin electronic display screens, which are flexible display screens, have come into the market. Compared with traditional display devices, flexible display screens have the advantages of being foldable and flexible, and are widely favored by consumers. The existing flat supporting structure obviously cannot meet the demands, such that supporting structures, which can adapt to bending demands of the flexible display screens, have been developing in the industry. The existing supporting structures that can adapt to bending requirements are usually composed of a plurality of hinges, and adjacent hinges, which are hinged by a structure such as a pin, are rotatable relative to each other. In the related art, the foldable devices usually do not include covering structures arranged on one side facing away from the flexible members, such that the foldable devices cannot meet the dustproof requirements.

### SUMMARY

The present disclosure provides a foldable device and an electronic device including the foldable device, which have a dustproof effect.

The present disclosure provides a foldable device, including a bendable mechanism, a connection mechanism, and a shielding mechanism. The connection mechanism is coupled to the bendable mechanism, and is slidable relative to the bendable mechanism as the bendable mechanism is folded; the shielding mechanism is arranged on an inner side of the bendable mechanism; the shielding mechanism is coupled to the connection mechanism; when the bendable mechanism is folded, the connection mechanism is capable of driving the shielding mechanism to slide relative to the bendable mechanism.

The present disclosure further provides an electronic device, including a flexible member, a housing, and the above foldable device; the housing includes a first frame and a second frame; the foldable device is arranged between the first frame and the second frame; the flexible member is arranged on the housing and the foldable device; the flexible member is folded or unfolded together with the foldable device.

The connection mechanism of the foldable device of the electronic device provided by the present disclosure is coupled to the bendable mechanism, and is slidable relative to the bendable mechanism as the bendable mechanism is folded. The shielding mechanism is arranged on an inner side of the bendable mechanism. The shielding mechanism is coupled to the connection mechanism. When the bendable mechanism is folded, the connection mechanism is capable of driving the shielding mechanism to slide relative to the bendable mechanism. Since the shielding mechanism is arranged on the inner side of the bendable mechanism, and is folded or unfolded together with the bendable mechanism, thus preventing dust and other impurities from entering the foldable device from the inner side.

### BRIEF DESCRIPTION OF THE DRAWINGS

In order to more clearly illustrate the technical solution of the present disclosure, the accompanying drawings required for describing the embodiments will be briefly described below. Apparently, the accompanying drawings in the following description are merely the embodiments of the present disclosure, and other drawings may be obtained by those skilled in the art according to these accompanying drawings without paying any creative labor.

FIG. 1 is a schematic view of a three-dimensional structure of an electronic device provided by an embodiment of the present disclosure.

FIG. 2 is an exploded, schematic view of the three-dimensional structure of a flexible display screen and a housing of the electronic device of FIG. 1.

FIG. 3 is an enlarged, schematic view of a three-dimensional structure of a foldable device of the electronic device of FIG. 2.

FIG. 4 is a schematic view of the three-dimensional structure of the foldable device of FIG. 3, but viewed from another aspect.

FIG. 5 is a partially exploded, schematic view of the three-dimensional structure of the foldable device of FIG. 3.

FIG. 6 is a partially exploded, schematic view of the three-dimensional structure of the foldable device of FIG. 4.

FIG. 7 is an exploded, schematic view of a three-dimensional structure of a middle hinge of a hinge assembly and two folding assisting assemblies of FIG. 5.

FIG. 8 is a schematic view of the three-dimensional structure of the middle hinge of the hinge assembly and the two folding assisting assemblies of FIG. 7, but viewed from another aspect.

FIG. 9 is an exploded, schematic view of the three-dimensional structure of the middle hinge of the hinge assembly of FIG. 7.

FIG. 10 is an exploded, schematic view of the three-dimensional structure of the middle hinge of the hinge assembly of FIG. 9, but viewed from another aspect.

FIG. 11 is an exploded, schematic view of a three-dimensional structure of a first connection hinge of a hinge assembly of FIG. 5.

FIG. 12 is a schematic view of the three-dimensional structure of the first connection hinge of the hinge assembly of FIG. 11, but viewed from another aspect.

FIG. 13 is an exploded, schematic view of a three-dimensional structure of a second connection hinge of a hinge assembly of FIG. 6.

FIG. 14 is a schematic view of the three-dimensional structure of the second connection hinge of the hinge assembly of FIG. 13, but viewed from another aspect.

FIG. 15 is an enlarged, schematic view of the three-dimensional structure of one of the two folding assisting assemblies of FIG. 7.

FIG. 16 is a schematic view of the three-dimensional structure of the folding assisting assembly of FIG. 15, but viewed from another aspect.

FIG. 17 is an exploded, schematic view of the three-dimensional structure of the folding assisting assembly of FIG. 15.

FIG. 18 is an exploded, schematic view of the three-dimensional structure of the folding assisting assembly of FIG. 16.

FIG. 19 is an exploded, schematic view of a three-dimensional structure of a shielding mechanism of the foldable device of FIG. 4.

FIG. 20 is a schematic view of an end structure of the foldable device of FIG. 3.

FIG. 21 is a cross-sectional view of FIG. 3, taken along the line of XXI-XXI.

FIG. 22 is a cross-sectional view of FIG. 3, taken along the line of XXII-XXII.

FIG. 23 is a cross-sectional view of FIG. 3, taken along the line of XXIII-XXIII.

FIG. 24 is a cross-sectional view of FIG. 3, taken along the line of XXIV-XXIV.

FIG. 25 is a cross-sectional view of FIG. 3, taken along the line of XXV-XXV.

FIG. 26 is a schematic view of the electronic device of FIG. 1 in a folded state.

FIG. 27 is a schematic view of a foldable device of the electronic device of FIG. 1 in an unfolded state.

FIG. 28 is a schematic view of an end structure of the foldable device of FIG. 27.

FIG. 29 is a cross-sectional view of FIG. 27, taken along the line of XXIX-XXIX.

FIG. 30 is a cross-sectional view of FIG. 27, taken along the line of XXX-XXX.

FIG. 31 is a cross-sectional view of FIG. 27, taken along the line of XXXI-XXXI.

FIG. 32 is a cross-sectional view of FIG. 27, taken along the line of XXXII-XXXII.

### DETAILED DESCRIPTION

The technical solutions in the embodiments of the present application will be described clearly and completely hereinafter with reference to the accompanying drawings in the embodiments of the present application. Apparently, the described embodiments are merely a part but not all embodiments of the present application. All other embodiments obtained by those skilled in the art based on the embodiments of the present application without paying any creative labor shall fall in the protecting scope of the present application.

In addition, the following embodiments are described with reference to the attached drawings for illustrating that the present disclosure may be applied to practice specific embodiments. Furthermore, the directional terms described in the present disclosure, such as “upper”, “lower”, “front”, “rear”, “left”, “right”, “inner”, “outer”, “side” and the like, are only directions with reference to the attached drawings. Therefore, the used directional terms are used for better and clearer illustration and understanding of the present disclosure, instead of indicating or implying that the device or element shall have a particular orientation and shall be structured and operated based on the particular orientation. Accordingly, these terms shall not be construed as limiting the present disclosure.

In the present disclosure, unless specified or limited otherwise, the terms “mounted,” “connected,” and “coupled” are understood broadly, such as fixed, detachable mountings, connections and couplings, or integrated, and can be mechanical or electrical or communicating mountings, connections and couplings, and also can be direct and via media indirect mountings, connections, and couplings, and further can be inner mountings, connections and couplings of two components or interaction relations between two components, which can be understood by those skilled in the art according to the detail embodiment of the present disclosure.

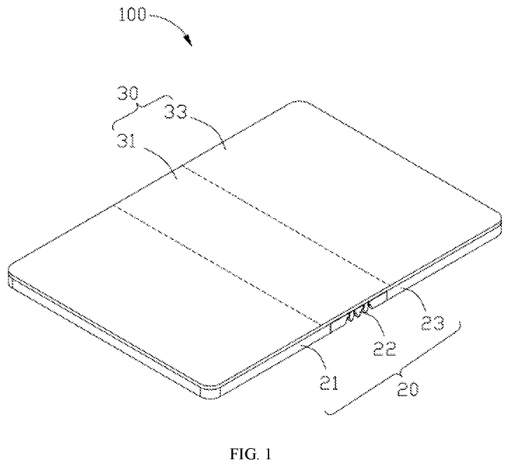

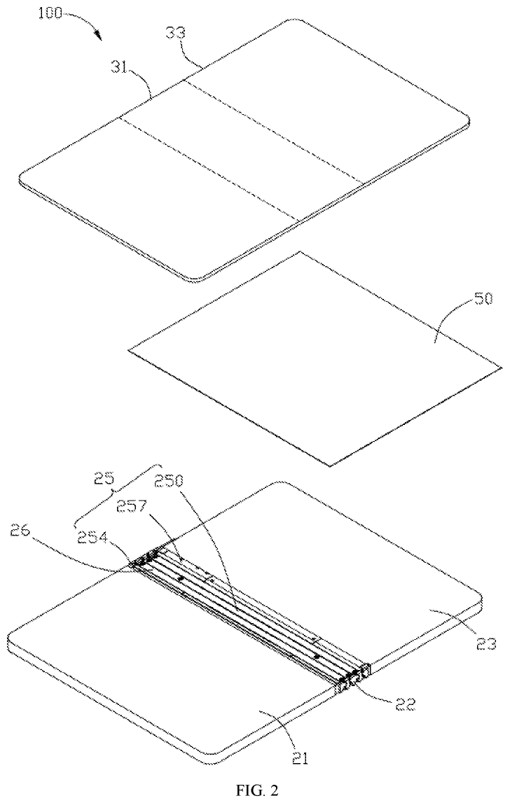

As illustrated in FIG. 1 to FIG. 6, an electronic device 100 provided by an embodiment of the present disclosure includes a housing 20 and a flexible member 30 arranged on the housing 20. The housing 20 includes a first frame 21, a second frame 23, and a foldable device 22 coupled to the first frame 21 and the second frame 23. The flexible member 30 is arranged on front surfaces of the first frame 21, the second frame 23, and the foldable device 22. The flexible member 30 is provided with a bendable area 31 corresponding to the foldable device 22 and two non-bendable areas 33 coupled to the two opposite sides of the bendable area 31. The foldable device 22 is configured to support the bendable area 31 of the flexible member 30. The flexible member 30 is folded or unfolded together with the foldable device 22. The foldable device 22 includes a bendable mechanism 25, two folding assisting assemblies 24, and a shielding mechanism 29. The two folding assisting assemblies 24 are arranged at two opposite ends of the bendable mechanism 25. The bendable mechanism 25 includes a middle hinge 250, which is located in a middle of the bendable mechanism 25, and connection hinges rotatably coupled to two opposite sides of the middle hinge 250. Each of the two folding assisting assemblies 24 includes a transmission mechanism 26, a connection mechanism 27, and a linkage mechanism 28. The transmission mechanism 26 is coupled to the middle hinge 250 and the connection hinges, and is configured to drive the connection hinges to move relative to the middle hinge 250. The connection mechanism 27 is coupled to the bendable mechanism 25, and is slidable relative to the bendable mechanism 25 as the bendable mechanism 25 is folded. The shielding mechanism 29 is arranged on an inner side of the bendable mechanism 25. The shielding mechanism 29 is coupled to the connection mechanism 28. When the bendable mechanism 25 is folded, the connection mechanism 27 is capable of driving the shielding mechanism 29 to slide relative to the bendable mechanism 25. Specifically, the shielding mechanism 29 includes two first shielding mechanisms 290 arranged at two opposite ends of the bendable mechanism 25, and a second shielding mechanism 295 arranged on a back surface of the bendable mechanism 25. Both of the two first shielding mechanisms 290 and the second shielding mechanism 295 are coupled to the connection mechanism 27. The connection hinges include a first connection hinge 254 and a second connection hinge 257. The first connection hinge 254 and the second connection hinge 257 are movably arranged on the two opposite sides of the middle hinge 250. The transmission mechanism 26 is coupled to the middle hinge 250, the first connection hinge 254, and the second connection hinge 257. The transmission mechanism 26 is configured to drive the first connection hinge 254 and the second connection hinge 257 to move relative to the middle hinge 250, thus achieving the bendable mechanism 25 to be folded or unfolded, and thereby allowing the electronic device 100 to be folded or unfolded.

In the embodiment, the flexible member 30 is a flexible screen. The front surface refers to a surface, which is faced toward a light emitting surface of the flexible screen. A back surface refers to a surface, which is faced away from the light emitting surface of the flexible screen. The electronic device 100 is, for example, but is not limited to, a mobile phone, tablet a computer, a display, a liquid crystal panel, an OLED panel, a TV, a smart watch, a VR head-mounted display, a car display, or any product or component with display function. The term “coupled” described in the embodiments of the present disclosure includes direct connections and indirect connections. For example, an element “A” coupled to an element “B” includes the following situations: the element “A” is directly connected to the element “B”; or the element “A” is connected to the element “B” by an element “C” or more other elements. The term “couplings” further includes two situations: integrated connection and non-integrated connection. The integrated connection refers to the element “A” and the element “B” are made in one piece and connected together. The non-integrated connection means refers to the element “A” and the element “B” are non-integrated and connected together.

The connection mechanism 27 of the foldable device 22 of the electronic device 100 provided by the present disclosure is coupled to the bendable mechanism 25, and is slidable relative to the bendable mechanism 25 as the bendable mechanism 25 is folded. The shielding mechanism 29 is arranged on an inner side of the bendable mechanism 25. The shielding mechanism 29 is coupled to the connection mechanism 27. When the bendable mechanism 25 is folded, the connection mechanism 27 is capable of driving the shielding mechanism 29 to slide relative to the bendable mechanism 25. Since the shielding mechanism 29 is arranged on the inner side of the bendable mechanism 25, and is folded or unfolded together with the bendable mechanism 25, thus preventing dust and other impurities from entering the foldable device 22 from the inner side.

The linkage mechanism 28 is coupled to the transmission mechanism 26. The transmission mechanism 26 includes two transmission members 262. The linkage mechanism 28 is coupled to the two transmission members 262. When one of the connection hinges located on one side of the middle hinge 250 rotates, an associated transmission member 262 of the transmission mechanism 26 adjacent to the connection hinge located on one side of the middle hinge 250 is driven by the connection hinge located on one side of the middle hinge 250 to rotate, and the associated transmission member 262 of the transmission mechanism 26 drives the other of the two transmission members 262 of the transmission mechanism 26 on an opposite side to the associated transmission member 262 to rotate via the linkage mechanism 28, and the connection hinge located on one side of the middle hinge 250 drives the other of the connection hinges located on the other side of the middle hinge 250 to rotate. Specifically, the two transmission members 262 include a first transmission member and a second transmission member. when the first connection hinge 254 rotates, the first transmission member adjacent to the first connection hinge 254 is driven by the first connection hinge 254 to rotate, the first transmission member drives the second transmission member on an opposite side to the first transmission member to rotate via the linkage mechanism 28, and a second connection hinge 257 on an opposite side to the first connection hinge 254 is driven by the second transmission member to rotate. When the second connection hinge 257 rotates, the second transmission member adjacent to the second connection hinge 257 is driven by the second connection hinge 257 to rotate, the second transmission member drives the first transmission member on an opposite side to the second transmission member to rotate via the linkage mechanism 28, and a first connection hinge 254 on an opposite side to the second connection hinge 257 is driven by the first transmission member to rotate. Such that the linkage of the bendable mechanism 25 can be realized.

Preferably, a movement of each of the connection hinges relative to the middle hinge 250 includes a rotating movement of an associated connection hinge relative to the middle hinge 250 and a sliding movement of the associated connection hinge relative to the middle hinge 250. That is, the associated connection hinge slides relative to the middle hinge 250 while rotating relative to the middle hinge 250. Specifically, the first connection hinge 254 slides relative to the middle hinge 250 while rotating relative to the middle hinge 250. The second connection hinge 257 slides relative to the middle hinge 250 while rotating relative to the middle hinge 250.

The connection mechanism 27 is coupled between the middle hinge 250 and the connection hinges. The connection mechanism 27 includes at least one guide rail rod. Each of the at least one guide rail rod is coupled between the middle hinge 250 and an associated connection hinge. When an associated connection hinge is movable relative to the middle hinge 250, an associated guide rail rod of the connection mechanism 27 slides relative to the associated connection hinge. Specifically, each of the at least one guide rail rod of the connection mechanism 27 is coupled between the middle hinge 250 and the first connection hinge 254, or between the middle hinge 250 and the second connection hinge 257. When the first connection hinge 254 and/or the second connection hinge 257 is/are movable relative to the middle hinge 250, the at least one guide rail rod of the connection mechanism 27 slides relative to the first connection hinge 254 and/or the second connection hinge 257.

The two folding assisting assemblies 24 are respectively coupled to two opposite ends of a back surface of the middle hinge 250 by a plurality of screws. A length of the middle hinge 250 along a bending axis of the bendable mechanism 25 is substantially equal to lengths of the first connection hinge 254 and the second connection hinge 257 along the bending axis of the bendable mechanism 25. A middle part of the first shielding mechanism 290 is coupled to an end of the middle hinge 250. Two opposite ends of the first shielding mechanism 290 are respectively coupled to ends of the first connection hinge 254 and the second connection hinge 257. The first shielding mechanism 290 is folded or unfolded with the bendable mechanism 25. The transmission mechanism 26 of each of the two folding assisting assemblies 24 includes two transmission members 262 arranged side by side. Ends of the two transmission members 262 away from the middle hinge 250 are respectively movably coupled to the first connection hinge 254 and the second connection hinge 257. The connection mechanism 27 of each of the two folding assisting assemblies 24 includes two guide rail rods arranged side by side. Ends of the two guide rail rods away from the middle hinge 250 are respectively slidably coupled to the first connection hinge 254 and the second connection hinge 257.

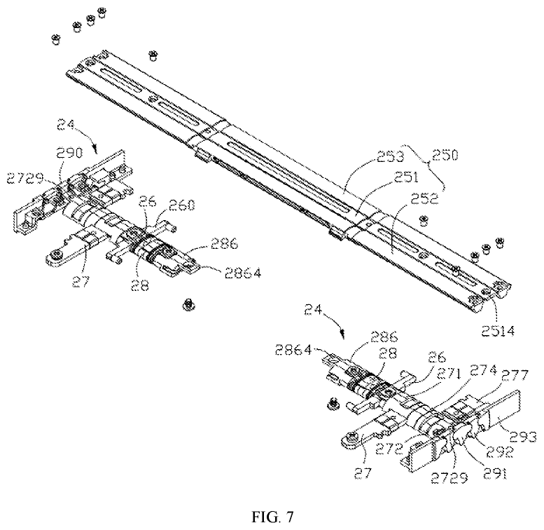

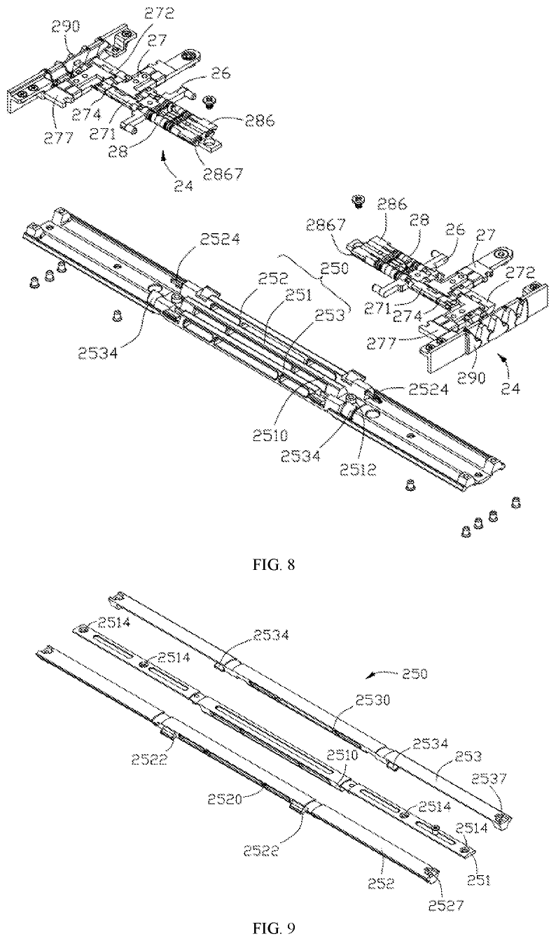

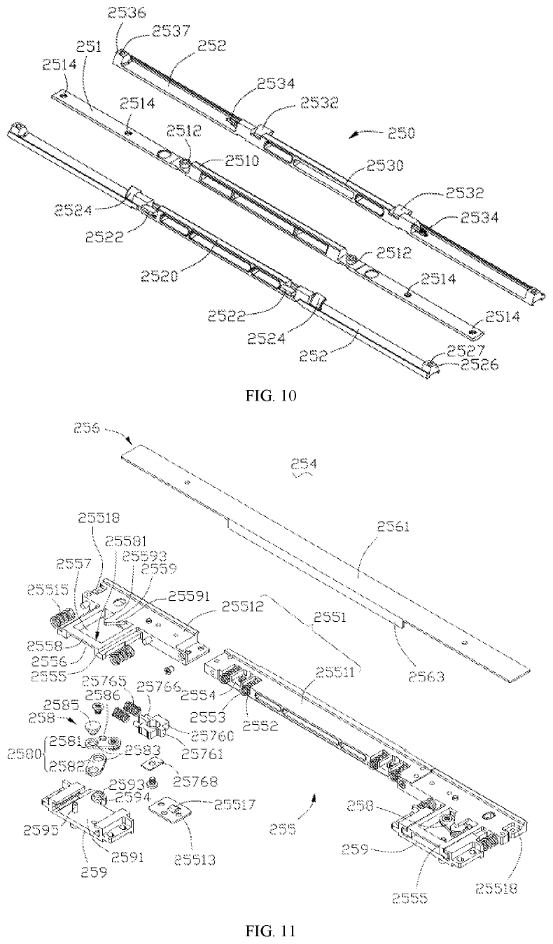

As illustrated in FIG. 7 to FIG. 10, the middle hinge 250 includes an intermediate hinge 251 and two rotating hinges located on two opposite sides of the intermediate hinge 251. Specifically, the two rotating hinges include a first rotating hinge 252 on a first side of the intermediate hinge 251 and a second rotating hinge 253 on a second side of the intermediate hinge 251. The intermediate hinge 251 is substantially in a strip shape. The intermediate hinge 251 includes a front surface being in a circular arc shape in cross section. A reinforcing bar 2510 is protruding from a middle of a back surface of the intermediate hinge 251. The back surface of the intermediate hinge 251 is provided with two connection columns 2512 at two opposite ends of the reinforcing bar 2510. Each of the two connection columns 2512 defines a connection hole in an axial direction. Two opposite ends of the front surface of the intermediate hinge 251 defines two countersunk holes 2514 arranged at interval, respectively. Each of the two countersunk holes 2514 penetrates the back surface of the intermediate hinge 251. One of the two countersunk holes 2514 located at the same end is adjacent to an associated end of the intermediate hinge 251, and the other one of the two countersunk holes 2514 located at the same end is adjacent to the associated connection column 2512. The two countersunk holes 2514 located at the two opposite ends of the intermediate hinge 251 are configured to couple the two folding assisting assemblies 24 respectively.

A structure of the first rotating hinge 252 is the same as a structure of the second rotating hinge 253. Here, only the first rotating hinge 252 will be described in further details. The first rotating hinge 252 is substantially in a strip shape. The first rotating hinge 252 includes a front surface being in a circular arc shape in cross section. A reinforcing bar 2520 is protruding from a middle of a back surface of the first rotating hinge 252. The back surface of the intermediate hinge 251 is respectively provided with two first arc-shaped guiding plates 2522 at two opposite ends of the reinforcing bar 2520. Each of the two first arc-shaped guiding plates 2522 is folded toward one side away from the intermediate hinge 251. The back surface of the intermediate hinge 251 is respectively provided with two second arc-shaped guiding plates 2524 adjacent to each of the two first arc-shaped guiding plates 2522. Each of the two second arc-shaped guiding plates 2524 is folded toward one side of the intermediate hinge 251. The two first arc-shaped guiding plates 2522 are located between the two second arc-shaped guiding plates 2524. Two positioning blocks 2526 protrude from the two opposite ends of the back surface of the first rotating hinge 252, respectively. Each of the two positioning blocks 2526 defines a connection hole 2527. A reinforcing bar 2530 is protruding from a middle of a back surface of the second rotating hinge 253. The second rotating hinge 253 includes a reinforcing bar 2530 located at a middle of a back surface of the second rotating hinge 253, two first arc-shaped guiding plates 2532 respectively located at two opposite ends of the reinforcing bar 2530, two second arc-shaped guiding plates 2534 respectively adjacent to each of the two first arc-shaped guiding plates 2532, and two positioning blocks 2536 located at two opposite ends of the back surface of the second rotating hinge 253, respectively. Each of the two positioning blocks 2536 defines a connection hole 2537.

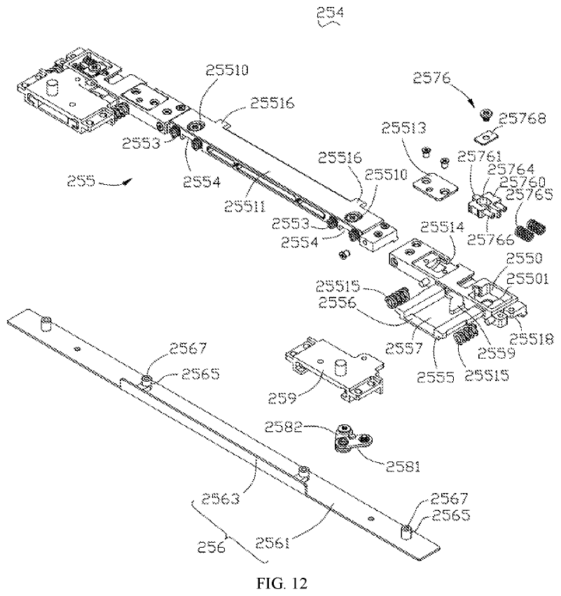

As illustrated in FIG. 11 and FIG. 12, the first connection hinge 254 includes a mounting frame 255 coupled to the middle hinge 250, a connection frame 256 slidably coupled to the mounting frame 255, two sliding members 259, and two fall-induced-compression resisting mechanisms 258. The mounting frame 255 includes a strip-shaped mounting plate 2551. The mounting plate 2551 includes a first plate body 25511 located in a middle of thereof and two second plate bodies 25512 fixedly coupled to two opposite ends of the first plate body 25511. An end of each of two second plate bodies 25512 facing to the first plate body 25511 defines a positioning groove. An end of the first plate body 25511 is accommodated in an associated positioning groove and fixed by a locking member. Two lugs 2555 vertically extend outwards from two opposite ends of one side of the mounting plate 2551 facing away from the middle hinge 250, respectively, that is, each of the two lugs 2555 vertically extends outwards form an end of each of the two second plate bodies 25512 facing away from the first plate body 25511. Two protrusion pieces 25516 are provided on the side of the first plate body 25511 facing away from the two lugs 2555. The two opposite ends of the first connection hinge 254 are respectively provided with two fixing grooves 25518.

A back surface of each of the two lugs 2555 defines a first sliding guide groove 2556, which is configured for receiving an associated one of the two fall-induced-compression resisting mechanisms 258, along an extending direction of thereof. Two opposite ends of the associated first sliding guide groove 2556 respectively penetrate an associated one of the two second plate bodies 25512 and an associated one of the two lugs 2555. A front surface of each of the two lugs 2555 is provided with a receiving groove 2557, which penetrates an associated first sliding guide groove 2556. An end of each of the two lugs 2555 at an associated receiving groove 2557 away from the associated one of the two second plate bodies 25512 is provided with a stopping bar 2558, and an end of the associated one of the two plugs 2555 adjacent to the associated one of the two second plate bodies 25512 is provided with a stopper 2559. Each of the two fall-induced-compression resisting mechanisms 258 is located between an associated stopping bar 2558 and an associated stopper 2559. The stopping bar 2558 is provided with a first stopping surface 25581 facing to the associated stopper 2559. The stopper 2559 includes an inclined second stopping surface 25591, and the first stopping surface 25581 is inclined relative to the second stopping surface 25591. Specifically, the stopper 2559 is an extending piece extending from the second plate body 25512 toward the receiving groove 2557. The receiving groove 25593 is surrounded by the receiving groove 2557 on one side of the stopper 2559. The second stopping surface 25591 is arranged on an end of the extending piece away from the second plate body 25512. The second stopping surface 25591 is faced away from the receiving groove 25593, and the second stopping surface 25591 adjacent to the end of the receiving groove 25593 is in an arc transition.

A side surface of the mounting plate 2551 faced toward the connection frame 256 defines two pairs of receiving grooves 2552, which are arranged at interval, between the two lugs 2555. Each of the two pairs of receiving grooves 2552 penetrates the side surface of the mounting plate 2551 provided with the two lugs 2555. Each of the two pairs of receiving grooves 2552 is provided with a first elastic member 2553. Specifically, two opposite ends of a front surface of the first plate body 25511 are respectively provided with a pair of receiving grooves 2552. Each first elastic member 2553 is a spring. A front surface of the mounting plate 2551 is provided with a strip groove 2554 between each of the two pairs of receiving grooves 2552. The strip groove 2554 extends along a direction perpendicular to a length direction of the mounting plate 2551 and penetrates the side surface of the mounting plate 2551 provided with the two lugs 2555. Two opposite ends of a back surface of the mounting plate 2551 defines two stepped holes 25510. Each of the two stepped holes 25510 penetrates the associated strip groove 2554. Each of the two stepped holes 25510 is a strip hole. Specifically, each of the two stepped holes 25510 extends along the associated strip groove 2554 in a length direction. Two opposite sides of the mounting plate 2551 is respectively provided with two second elastic members 25515 at each of the two lugs 2555. Specifically, two positioning columns protrude from two opposite sides of the mounting plate 2551, respectively. Each of the two second elastic members 25515 is sleeved on an associated one of the two positioning columns. Each of the two second elastic members 25515 is a spring.

As illustrated in FIG. 12, two ends of the back surface of the mounting plate 2551 respectively define two mounting grooves 2550 at a position adjacent to each of the two lugs 2555 along the mounting plate 2551 in a length direction. Each of the two mounting grooves 2550 is adjacent to one end of an associated first sliding guide groove 2556, and is in air communication with the associated first sliding guide groove 2556. The mounting plate 2551 defines a through hole 25501 at a bottom wall of each of the two mounting grooves 2550. A positioning mechanism 2576 is provided in the first connection hinge 254. The positioning mechanism 2576 is configured to position the bendable mechanism 25 being in a folded state or an unfolded state. Specifically, the positioning mechanism 2576 includes a positioning member 25760, which is slidably arranged in the mounting groove 2550, and an elastic member 25765, which is elastically abutting against the positioning member 25760. One end of the positioning member 25760 is provided with a fixing block 25761, of which an outer peripheral surface is an arc surface. Two connection rods 25766 protrude from two opposite ends of one side of the positioning member 25760 facing away from the fixing block 25761, respectively. The positioning member 25760 defines a strip-shaped sliding guide groove 25764 between the fixing block 25761 and the connection rod 25766. The sliding groove 25764 extends along the mounting plate 2551 in the length direction and penetrates front and back surfaces of the positioning member 25760. The positioning member 25760 is slidably received in the mounting groove 2550. The two elastic members 25765 are respectively sleeved on the two connection rods 25766 and coupled to an inner wall of the mounting groove 2550. The two elastic members 25765 can push the positioning member 25760 to slide along the mounting groove 2550, to allow the block 25761 to be inserted into an associated first sliding guide groove 2556. In the embodiment, the elastic member 25765 is a spring, which is sleeved on the connection rod 25766. One end of the spring is sleeved on the connection rod 25766, and the other end of the spring abuts against the inner wall of the mounting groove 2550. The positioning mechanism 2576 further includes a cover plate 25768 and a locking member. The locking member passes through a through hole of the cover plate 25768 and is locked to the first connection hinge 254 to allow the positioning member 25760 to be slidably received in the mounting groove 2550.

The back surface of the mounting plate 2551 adjacent to each of the two lugs 2555 defines a transmission groove 25514. The transmission groove 25514 is substantially an arc-shaped groove. The transmission groove 25514 penetrates the side surface of the mounting plate 2551 facing away from the two lugs 2555. The transmission groove 25514 extends along a direction perpendicular to a length direction of the mounting plate 2551. A bottom surface of the transmission groove 25514 is an arc-shaped surface. The arc surface is curved toward the front surface of the mounting plate 2551, that is, a depth direction of the transmission groove 25514 is a thickness direction of the mounting plate 2551. In the embodiment, the transmission groove 25514 is formed on a back surface of each of the two second plate bodies 25512 adjacent to the two lugs 2555. Each of the two second plate bodies 25512 defines a recess around the transmission groove 25514. The recess is configured to fix the cover plate 25513. A side surface of the cover plate 25513 facing to the mounting plate 2551 is provided with a protrusion 25517 corresponding to the transmission groove 25514. The protrusion 25517 is provided with an arc-shaped outer peripheral surface. When the cover plate 25513 is accommodated in the recess, the protrusion 25517 is accommodated in the transmission groove 25514, such that the outer peripheral surface of the protrusion 2551 and the arc-shaped surface of the transmission groove 25514 cooperatively form the arc-shaped groove.

The sliding member 259 is slidably sleeved on each of the two lugs 2555. The fall-induced-compression resisting mechanism 258 is movably received in the receiving groove 2557 of each of the two lugs 2555. Specifically, a front surface of the sliding member 259 defines a sliding guide groove 2591. An associated lug 2555 can be slidably inserted into the sliding guide groove 2591. The sliding member 259 corresponding to the receiving groove 2557 of the lug 2555 is provided with a connection column 2593 protruding into the sliding guide groove 2591. The connection column 2591 axially defines a connection hole 2594. The sliding member 259 corresponding to the receiving groove 2557 of the lug 2555 is provided with a first stopper 2595 toward the sliding guide groove 2591. The connection post 2393 is located at one end of the sliding member 259 adjacent to one side of the mounting plate 2551. The first stopper 2595 is located away from one side of the connection post 2393. The fall-induced-compression resisting mechanism 258 includes a connection rod 2580 and a connection member 2585. The connection rod 2580 includes a first connection rod 2581 and a second connection rod 2582. The first connection rod 2581 and the second connection rod 2582 are rectangular pieces. Two opposite ends of each of the first connection rod 2581 and the second connection rod 2582 are provided with two arc-shaped surfaces, respectively. Two opposite ends of each of the first connection rod 2581 and the second connection rod 2582 are provided with two through holes 2583, respectively. Both of the first connection rod 2581 and the second connection rod 2582 include a first end and a second end opposite to the first end. The connection member 2585 is inserted into an associated through hole 2583 at the second end of the first connection rod 2581 and an associated through hole 2583 at the second end of the second connection rod 2582, to allow the first connection rod 2581 to be rotatably coupled to the second connection rod 2582. The associated through hole 2583 at the first end of the first connection rod 2581 is rotatably coupled to the connection column 2573 of the sliding member 259. A stopper block 2586 protrudes from a middle of one end of the first connection rod 2581. A thickness of the first connection rod 2581, where contacts the second stopping surface 25591 of the stopper 2559, can be increased by the stopper block 2586.

The connection frame 256 includes a strip-shaped connection plate 2561 and a connection piece 2563 arranged on one side of the connection plate 2561 facing away from the middle hinge 250. The connection piece 2563 extends along a direction perpendicular to a length direction of the connection plate 2561. An extending length of the connection piece 2563 is smaller than a length of the connection plate 2561. The connection plate 2561 is provided with four connection posts 2575. The four connection posts 2575 are arranged along a length direction of the connection plate 2561. The connection posts 2565 located at two ends of the connection plate 2561 correspond to the through holes 25501 located at two opposite ends of the mounting plate 2551, respectively. The two connection posts 2565 located at a middle part of the connection plate 2561 corresponding to the stepped holes 25510 of the mounting plate 2551. Two opposite ends of the connection piece 2563 are respectively coupled to the two connection posts 2565 located at the middle part of the connection plate 2561 by reinforcing ribs, thus enhancing the strength of the connection piece 2563. Each of the four connection column 2565 axially defines a connection hole 2567.

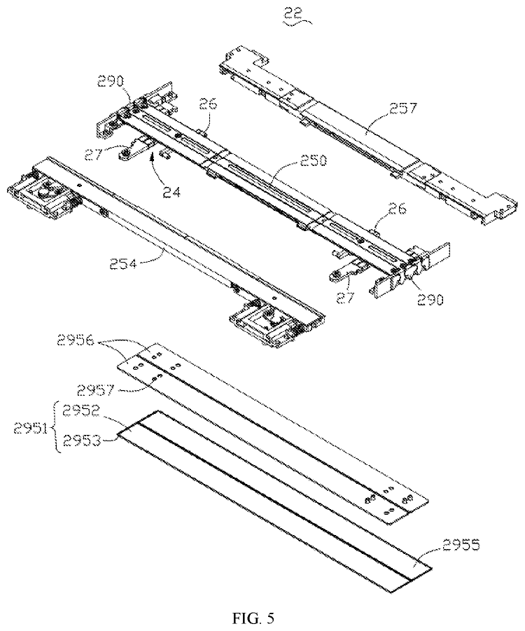

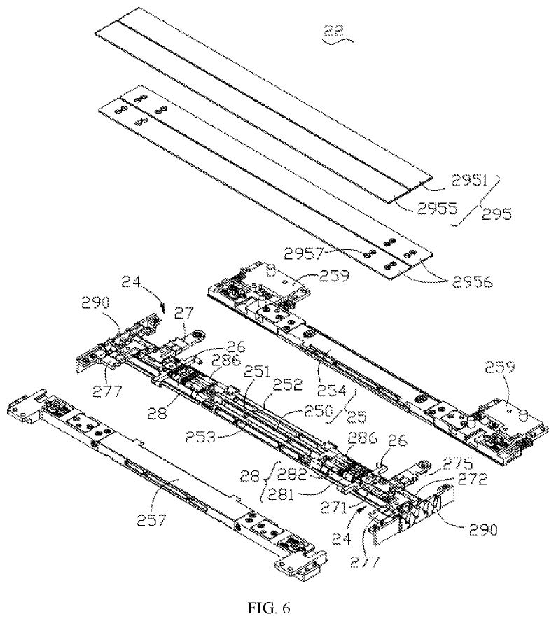

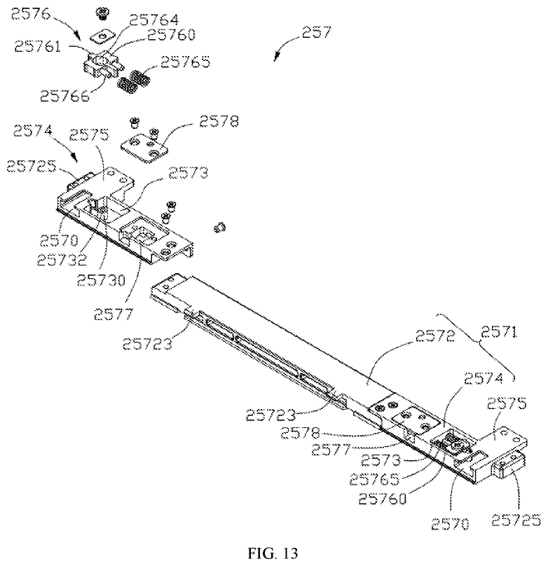

As illustrated in FIG. 5, FIG. 6, FIG. 12, and FIG. 13, in assembling of the first connection hinge 254, the connection rod 25766 of each positioning member 25760 is inserted into the elastic member 25765 and then mounted in the mounting groove 2550 of the mounting frame 255 to allow the sliding guide groove 25764 of the positioning member 25760 to be aligned with the through hole 25501. The positioning member 25760 can slide along the sliding guide groove 25764. The elastic member 25765 elastically abuts against between the positioning member 25760 and the inner wall of the mounting groove 2550. The elastic member 25765 abuts against the positioning member 25760 to slide along the sliding guide groove 25764, such that the fixing block 25761 extends into an associated first sliding guide groove 2556. The two connection rods 2580 are accommodated in the associated sliding guide groove 2591 of each of the two sliding members 259, such that the through hole 2583 of the second connection rod 2582 of each connection rod 2580 is aligned with an associated connection column 2593, and the locking member is inserted into the through hole 2583 and the connection hole 2594 to allow the first end of the second connection rod 2582 to be rotatably coupled with the sliding members 259. The second elastic members 25515 are respectively sleeved on the positioning columns of the mounting plate 2551. The two sliding members 259 are respectively sleeved on the two lugs 2555 of the mounting frame 255, such that the second connection rod 2582 of each connection rod 2580 is accommodated in the receiving groove 25593, and the first connection rod 2581 is adjacent to the second stopping surface 25591 of the second stopper 2559. At this time, each of the two sliding members 259 is sleeved on an associated lug 2555 and coupled to an associated one of the two second elastic members 25515. The connection frame 256 is covered on the mounting frame 255, such that the four connection columns 2565 of the connection frame 256 can be slidably inserted into the two strip grooves 2554 and the two through holes 25501 of the mounting frame 255. The connection pieces 2563 of the connection frame 256 abuts against the first elastic member 2553 on the mounting frame 255. The connection plate 2561 of the connection frame 256 covers the mounting frame 255. The two locking members are respectively inserted into the stepped holes 25510 on the back of the mounting frame 255 and coupled to the connection hole 2567 of the connection column 2565, to allow the connection frame 256 to be slidable relative to the mounting frame 255 along the stepped holes 25510. Each of the two locking members respectively inserted into the through hole, defined by an associated one of the two cover plates 25768, the sliding guide groove 25764, defined by an associated one of the two positioning members 25760 is locked in an associated connection hole 2567 defined on the connection frame 256. At this time, the first elastic member 2553 is elastically clamped between the connection piece 2563 and the mounting frame 255. Each of the four connection columns 2565 can slide along an associated strip groove 25510. The two sliding members 259 can slide relative to the mounting frame 255. The two connection rods 2580 can rotate in an associated receiving groove 2557.

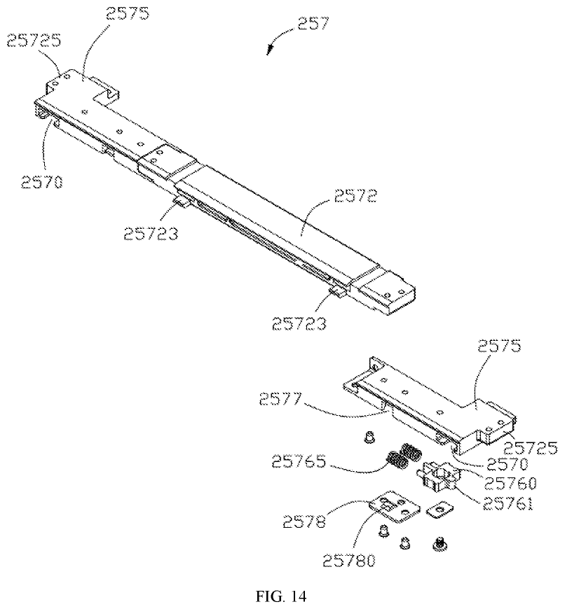

As illustrated in FIG. 13 and FIG. 14, the second connection hinge 257 includes a strip-shaped connection plate 2571. The connection plate 2571 includes a first plate body 2572 located in a middle of thereof and two second plate bodies 2574 fixedly coupled to two opposite ends of the first plate body 2572. The first plate body 2572 and each of the two second plate bodies 2574 can be coupled to each other by a fixing block and a fixing groove. The first plate body 2572 and each of the two second plate bodies 2574 can also be coupled to each other by screwing or gluing. In the embodiment, an end of each of the two second plate bodies 2574 facing to the first plate body 2572 defines a positioning groove. Each end part of the first plate 2572 is accommodated in the positioning groove and fixed by a locking member. Two opposite ends of the second connection hinge 257 facing away from the middle hinge 250 are respectively provided with two lugs 2575. Specifically, one side of the first board 2572 facing away from the two lugs 2575 is provided with two protrusion pieces 25723. The two opposite ends of the second connection hinge 257 are respectively provided with two fixing blocks 25725. Each of the two fixing blocks 25725 is provided with a connection hole.

Two opposite ends of one side of the connection plate 2571 facing the middle hinge 250 are respectively provided with two second sliding guide grooves 2570 arranged at interval. Each of the two second sliding guide grooves 2570 extends along a direction perpendicular to a length direction of the connection plate 2571. A back surface of the connection plate 2571 defines a mounting groove 2573 at a position adjacent to each of the two second sliding guide grooves 2570. One end of each mounting groove 2573 adjacent to an associated second sliding guide groove 2570 is in air communication with an associated second sliding guide groove 2570. A positioning column 25730 protrudes from the connection plate 2571 toward each of each mounting groove 2573. Each positioning column 25730 axially defines a connection hole 25732. A positioning mechanism 2576 is also provided in the second connection hinge 257. The positioning mechanism 2576 is configured to position the bendable mechanism 25 being in the folded state or the unfolded state. Specifically, the positioning mechanism 2576 includes a positioning member 25760, which is slidably received in the mounting groove 2573, and an elastic member 25765, which elastically abuts against the positioning member 25760. One end of the positioning member 25760 is provided with a fixing block 25761, of which an outer peripheral surface is an arc surface. Two connection rods 25766 protrude from two opposite ends of one side of the positioning member 25760 facing away from the fixing block 25761, respectively. The positioning member 25760 defines a strip-shaped sliding guide groove 25764 between the fixing block 25761 and the connection rod 25766. The sliding groove 25764 extends along the connection plate 2571 in the length direction and penetrates front and back surfaces of the positioning member 25760. The positioning member 25760 is slidably received in the mounting groove 2573. The two elastic members 25765 are respectively sleeved on the two connection rods 25766 and coupled to an inner wall of the mounting groove 2573. The two elastic members 25765 can abut against the positioning member 25766 to slide along the mounting groove 2573, to allow the fixing block 25761 to be inserted into the an associated second sliding guide groove 2570.

The back surface of the connection plate 2571 adjacent to each of the two lugs 2575 defines a transmission groove 2577. The transmission groove 2577 is substantially an arc-shaped groove. The transmission groove 2577 penetrates the side surface of the connection plate 2571 facing away from the two lugs 2575. The transmission groove 2577 extends along a direction perpendicular to a length direction of the connection plate 2571. A bottom surface of the transmission groove 2577 is an arc-shaped surface. The arc surface is curved toward the front surface of the connection plate 2571, that is, a depth direction of the transmission groove 2577 is a thickness direction of the connection plate 2571. In the embodiment, the transmission groove 2577 is formed on a back surface of each of the two second plate bodies 25512 adjacent to the two lugs 2575. Each of the two second plate bodies 2574 defines a recess around the transmission groove 2577. The recess is configured to fix the cover plate 2578. A side surface of the cover plate 2578 facing to the connection plate 2571 is provided with a protrusion 25780 corresponding to the transmission groove 2577. The protrusion 25780 is provided with an arc-shaped outer peripheral surface. When the cover plate 2578 is accommodated in the recess, the protrusion 25780 is accommodated in the transmission groove 2577, such that the outer peripheral surface of the protrusion 25780 and the arc-shaped surface of the transmission groove 2577 cooperatively form the arc-shaped groove.

As illustrated in FIG. 5, FIG. 6, FIG. 12, and FIG. 13, in assembling of the second connection hinge 257, the connection rod 25766 of each positioning member 25760 is inserted into the elastic member 25765 and then mounted in the mounting groove 2573 of the connection plate 2571, such that the positioning column 25730 in the mounting groove 2573 is inserted into the sliding guide groove 25764 of the positioning member 25760. The positioning member 25760 can slide along the sliding guide groove 25764. The elastic member 25765 elastically abuts against between the positioning member 25760 and an inner wall of the mounting groove 2573. The elastic member 25765 abuts against the positioning member 25760 to slide along the sliding guide groove 25764, such that the fixing block 25761 extends into an associated second sliding guide groove 2570.

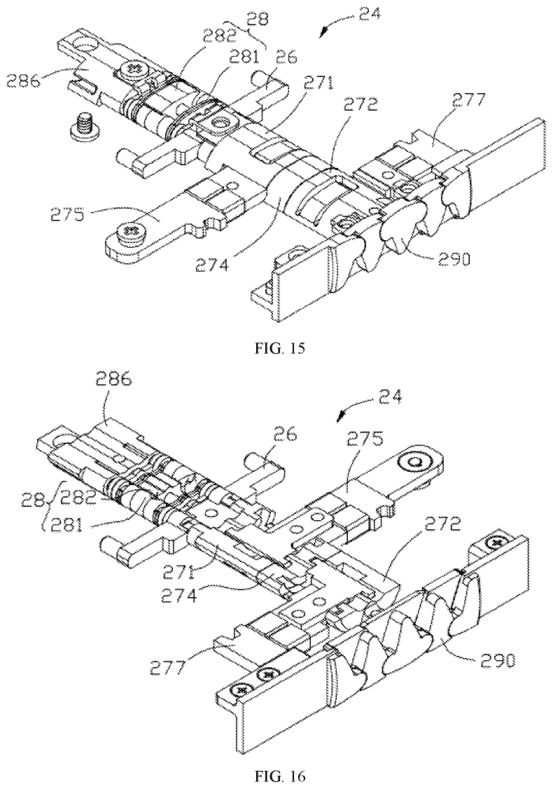

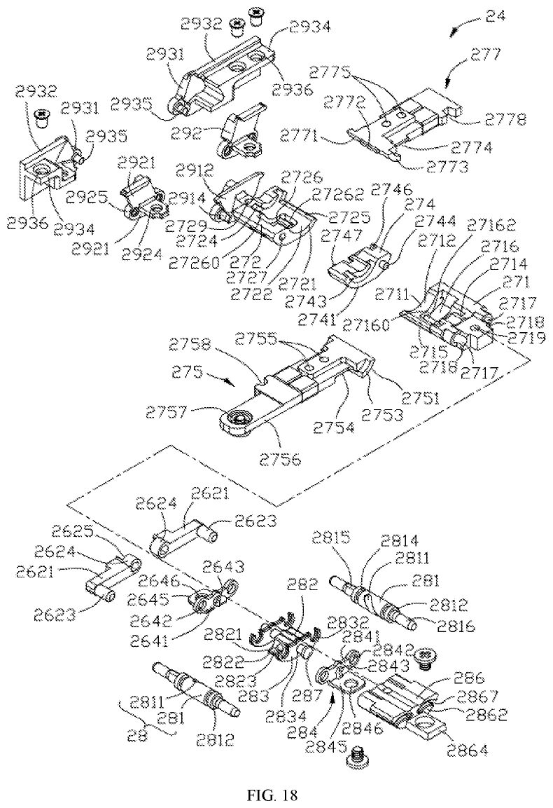

As illustrated in FIG. 15 and FIG. 18, the transmission mechanism 26 includes two transmission members 262, which are arranged on two opposite sides of the folding assistance assembly 24, and a first connection frame 264. The first connection frame 264 is configured to couple the two transmission members 262 with the folding assistance assembly 24. Each of the two transmission members 262 is substantially L-shaped. Each of the two transmission members 262 includes a strip-shaped transmission rod 2621, a sliding guide rod 2623 arranged at one end of the transmission rod 2621, and a connection cylinder 2624 arranged at one end of the transmission rod 2621 facing way from the sliding guide rod 2623. The sliding guide rod 2623 extends along a direction perpendicular to a length direction of the transmission rod 2621. One end of the transmission rod 2621 provided with the sliding guide rod 2623 in a circular arc. The sliding guide rod 2623 is a round rod. The connection cylinder 2624 in an axial direction is perpendicular to the transmission rod 2621 in a length direction. An end surface of the connection cylinder 2624 facing away from the transmission rod 2621 is substantially an arc surface. A cross section of an inner cavity of the connection cylinder 2624 is substantially kidney-shaped. One end of the connection cylinder 2624 defines a notch 2625. A central angle of the notch 2625 corresponding to the connection cylinder 2624 is greater than 180 degrees. The first connection frame 264 includes a connection piece 2641 and an overlapping piece 2645 arranged at a middle of a side of the connection piece 2641. The overlapping piece 2645 in an extending direction is perpendicular to the connection piece 2641 in an extending direction. Two opposite ends of the connection piece 2641 respectively define two rotating holes 2642. Two opposite end surface of the connection piece 2641 are respectively two arc surfaces. A middle of the connection piece 2641 defines a through hole 2643. A middle of one end of the overlapping piece 2645 away from the connection piece 2641 defines a connection hole 2646.

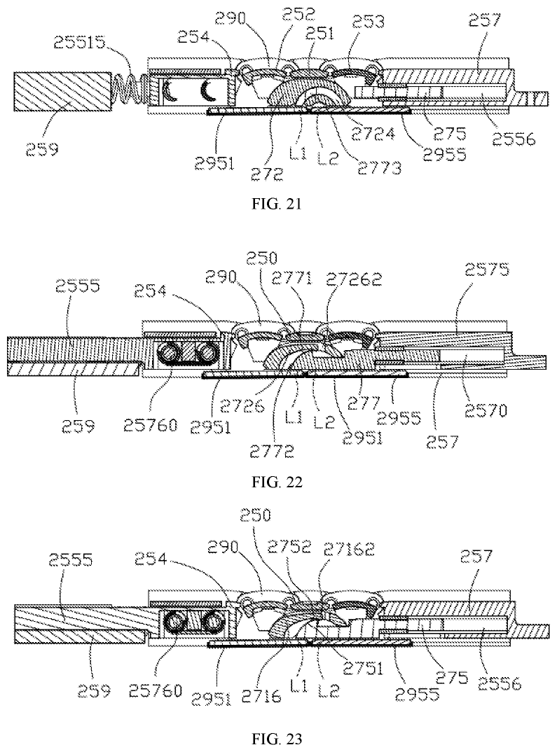

The connection mechanism 27 includes at least one guide rail blocks and at least one guide rail rods coupled to the at least one of guide rail blocks. Specifically, the at least one of guide rail blocks includes a first guide rail block 271, a second guide rail block 272, and a third guide rail block 274 located between the first guide rail block 271 and the second rail guide rail block 272. The at least one of guide rail rods includes a first guide rail rod 275 rotatably coupled between the first guide rail block 271 and the third rail guide rail block 274 and a second guide rail rod 277 rotatably coupled between the second guide rail block 272 and the third rail guide rail block 274. The first guide rail rod 275 and the second guide rail rod 277 are respectively rotatably coupled to the at least one of guide rail blocks by different virtual axes. The virtual axes include a first virtual axis L1 and a second virtual axis L2. Specifically, the first guide rail rod 275 rotates along the first virtual axis L1 (as shown in FIG. 21), and the second guide rail rod 277 rotates along the second virtual axis L2 (shown in FIG. 21).

The first guide rail block 271 includes an arc-shaped front surface 2710. One end of a back surface of the first guide rail rod 271 adjacent to the third guide rail rod 274 defines a first rotating cavity 2711. A bottom surface of the first rotating cavity 2711 of the first guide rail rod 271 is defined as a first guide rail curve surface 2712. An end of the first guide rail curve surface 2712 of the first guide rail rod 271 facing away from the third guide rail rod 274 defines an arc-shaped first guide groove 2714. An axis of the first guide rail curve surface 2712 is colinear with an axis of the first guide groove 2714. One side of the first rotating cavity 2711 of the first guide rail rod 271 away from the notch 2715 defines a strip-shaped through groove 27160. The through groove 27160 is in air communication with the first rotating cavity 2711. The through groove 27160 extends along a circumferential direction of the first guide rail curve surface 2712 to a position adjacent to the notch 2715. The through groove 27160 is provided with an elastic first clamping matching part 2716. The first clamping matching part 2716 is an arc-shaped piece. The arc-shaped piece extends from an end of the through groove 27160 facing away from the notch 2715 to the through groove 27160. An end of the first clamping matching part 2716 is provided with a fastening strip 27162 protruding into the first rotating cavity 2711. The fastening strip 27162 extends along a width direction of the first fitting part 2716. An outer peripheral surface of the fastening strip 27162 is a circular arc surface. Two opposite sides of the first guide rail rod 271 facing away from the first rotating cavity 2711 respectively define two connection holes 2717 along an axial direction of the first guide rail curve surface 2712. An associated one of the two connection holes 2717 on the same side as the notch 2715 extends to a position adjacent to the first guide groove 2714. An associated one of the two connection holes 2717 on different sides with the notch 2715 penetrates the first guide rail rod 271. Two opposite sides of an end of the connection hole 2717 facing away from the first rotating cavity 2711 respectively define two notches 2718. A central angle of each of the two notches 2718 corresponding to an associated one of the two connection holes 2717 is greater than 180 degrees. A middle of one end of the first guide rail block 271 facing away from the first rotating cavity 2711 defines a positioning hole 2719.

The second rail guide rail block 272 is fixedly coupled to the first shielding mechanism 290. A structure of the second guide rail block 272 is similar to a structure of the first guide rail block 271. Specifically, the second guide rail block 272 includes an arc-shaped front surface 2720. One end of a back surface of the second guide rail block 272 adjacent to the third guide rail block 274 defines a second rotating cavity 2721. A bottom surface of the second rotating cavity 2721 of the second guide rail block 272 is defined as a second guide rail curve surface 2722. One end of the second guide rail curve surface 2722 of the second guide rail block 272 facing away from the third guide rail block 274 defines an arc-shaped second guide groove 2724. An axis of the second guide rail curve surface 2722 is collinear with an axis of the second guide groove 2724. One side of the second rotating cavity 2721 of the second guide rail block 272 defines a notch 2725. One side of the second rotating cavity 2721 of the second guide rail block 272 facing away from the notch 2725 defines a strip-shaped through groove 27260. The through groove 27260 is in air communication with the rotating cavity 2721. The through groove 27260 extends along a circumferential direction of the second guide rail curve surface 2722 to a position adjacent to the notch 2725. The through groove 27260 is provided with an elastic second clamping matching part 2726. The second clamping matching part 2726 is an arc-shaped piece. The arc-shaped piece extends from an end of the through groove 27260 facing away from the notch 2725 to the through groove 27260. A matching groove 27262 is formed between an end of the second clamping matching part 2726 and an inner surface of one end of the through groove 27260 adjacent to the notch 2725. The matching groove 27262 extends along an axial direction of the second fitting part 2726. One side of the second guide rail block 272 facing away from the notch 2725 defines a connection hole 2727 along an axial direction of the second guide rail curve surface 2722. A middle of the second guide rail block 272 facing away from the rotating cavity 2721 defines a positioning hole 2729. One end of the second guide rail block 272 defined the positioning hole 2729 is fixedly coupled to the first shielding mechanism 290.

The third guide rail block 274 includes an arc-shaped front surface 2740, a back surface facing away from the front surface 2740, and two opposite side surfaces 2741. The side surface 2741 faced toward the first guide rail block 271 is provided with a guide groove 2743 and a positioning column 2744. The positioning column 2744 corresponds to the connection hole 2717 on the side of the first guide rail block 271 away from the notch 2715. When the positioning column 2744 is inserted into the connection hole 2717, to allow the third guide rail block 274 to be coupled to the first guide rail block 271. The guide groove 2743 corresponds to the first guide groove 2714 of the first guide rail block 271, that is, an axis of the guide groove 2743 is colinear with an axis of the first guide groove 2714. The side surface 2741 facing to the second guide rail block 272 is provided with a guide groove 2746 and a positioning column 2747. The positioning column 2747 corresponds to the connection hole 2727 on the side of the second guide rail block 274 away from the notch 2725. When the positioning column 2747 is inserted into the connection hole 2727 to allow the third guide rail block 274 to be coupled to the second guide rail block 272. The guide groove 2746 corresponds to the second guide groove 2724 of the second guide rail block 272, that is, an axis of the guide groove 2746 is colinear with an axis of the second guide groove 2724. The axis of the guide groove 2743 is parallel to the axis of the guide groove 2746.

One end of the first guide rail rod 275 is provided with a first guide rail matching surface 2751. The first guide rail matching surface 2751 is an arc surface corresponding to the first guide rail curve surface 2712 of the first guide rail block 271, that is, when the first guide rail rod 275 is coupled to the first guide rail block 271, the first guide rail matching surface 2751 slidably fits on the first guide rail curve surface 2712, and the first guide rail matching surface 2751 rotates along a track of the first guide rail curve surface 2712. Such that the axis of the first guide rail matching surface 2751 is collinear with the axis of the first guide rail curve surface 2712, and the first guide rail rod 275 rotates relative to the first guide block 271 along the first virtual axis L1. Two opposite ends of the first guide rail matching surface 2751 of the first guide rail rod 275 is provided with two first sliding guide rails 2753 along the first guide rail matching surface 2751, and the two first sliding guide rails 2753 respectively correspond to the first guide groove 2714 of the first guide rail block 271 and the guide groove 2743 of the third guide rail block 274. A middle of the first guide rail matching surface 2751 of the first guide rail rod 275 adjacent to one side of the first guide rail rod 275 is provided with a first clamping part 2752. Preferably, the first clamping part 2752 is a strip-shaped fastening point extending along an axial direction of the first guide rail matching surface 2751. A position of a front surface of the first guide rail rod 275 adjacent to the first sliding guide rail 2753 defines an evasion groove 2754. A position of a back surface of the first guide rail rod 275 adjacent to the evasion groove 2754 defines two fixing holes 2755. One end of the first guide rail rod 275 away from the first guide rail matching surface 2751 extends an extension piece 2756 along a length direction of the first guide rail rod 275. An end of the extension piece 2756 defines a connection hole 2757. One side of the first guide rail rod 275 facing away from the first guide rail block 271 defines at least one positioning opening 2758 at apposition adjacent to the extension piece 2756.

A structure of the second guide rail rod 277 is similar to a structure of the first guide rail rod 275. Specifically, one end of the second guide rail rod 277 is provided with a second guide rail matching surface 2771. The second guide rail matching surface 2771 is an arc surface corresponding to the second guide rail curve surface 2722 of the second guide rail block 272, that is, when the second guide rail rod 277 is coupled to the second guide rail block 272, the second guide rail matching surface 2771 can rotate along a track of the second guide rail curve surface 2722, and the second guide rail matching surface 2771 rotates along a track of the second guide rail curve surface 2722. Such that, an axis of the second guide rail matching surface 2771 is collinear with an axis of the second guide rail curve surface 2722, and the second guide rail rod 277 is rotated relative to the second guide rail block 272 along the second virtual axis L2. Two opposite ends of the second guide rail matching surface 2771 of the second guide rail rod 277 are respectively provided with two second sliding rails 2773 along the second guide rail matching surface 2771. The two second sliding rails 2773 respectively correspond to the second guide groove 2724 of the second guide rail block 272 and the guide groove 2746 of the third guide rail block 274. A middle of the second guide rail matching surface 2771 of the second guide rail rod 277 adjacent to one side of a front surface of the second guide rail rod 277 is provided with a second clamping part 2772. Preferably, the second clamping part 2772 is a strip-shaped convex wall extending along an axial direction of the second guide rail matching surface 2771. A front surface of the second guide rail rod 277 adjacent to the two second sliding rail 2773s defines an evasion groove 2774. A back surface of the second guide rail rod 277 adjacent to a position of the evasion groove 2774 defines two fixing holes 2775. One side of the second guide rail rod 277 facing away from the second guide rail block 271 defines at least one positioning opening 2778 at a position adjacent to the extension piece 2756.

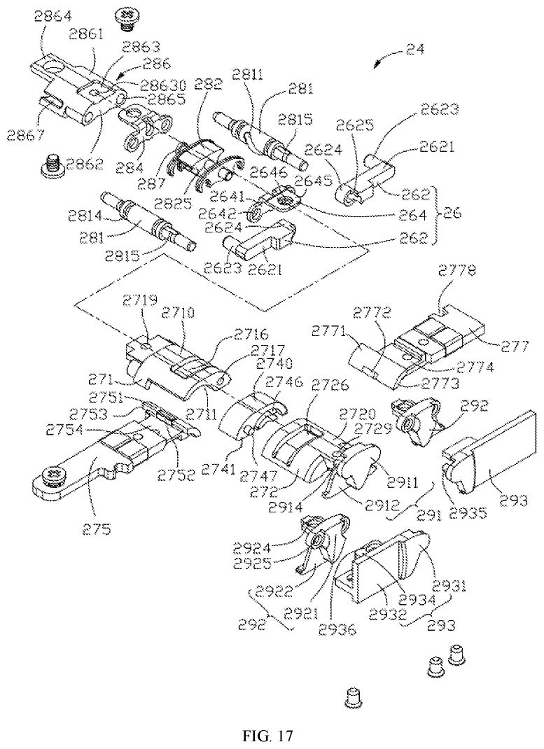

As illustrated in FIG. 17 and FIG. 18, each of the two linkage mechanisms 28 includes two shafts 281, which are arranged side by side and in parallel, a linkage member 282, two groups of fixing pieces 283, a second connection frame 284, a fixing block 286, and a connection column 287. The two shafts 281 are arranged on two opposite sides of the linkage member 282. The two groups of fixing pieces 283 and the second connection frame 284 are configured to couple the two shafts 281 and the linkage member 282. The two shafts 281 are coupled to the two transmission members 262 respectively. The linkage member 282 is coupled between the two shafts 281. When an associated transmission member 262 rotates, an associated one of the two shafts 281 is driven by the associated transmission member 262 to rotate. The associated one of the two shafts 281 drives the other of the two shafts 281 to rotate by the linkage member 282, such that the other of the two transmission members 262 also rotates. The two shafts 281 are symmetric around a center line of the linkage member 282.

Each of the two shafts 281 and the linkage member 282 are coupled by a spiral guide groove 2811 and a sliding block 2821 matched with the spiral guide groove 2811. One of the two shafts 281 rotates to allow the sliding block 2821 to be slidable in an associated guide groove 2811. Such that the linkage member 282 is moved along a direction parallel to an axis of each of the two shafts 281 to drive the other of the two shafts 281 to rotate together.

The linkage member 282 is a linkage block. The linkage member 282 includes two opposite side surfaces 2822. The two opposite side surfaces 2822 define respectively two opposite receiving grooves 2823 along axial directions of the two shafts 281. A cross section of each of the two receiving grooves 2823 is arc-shaped. The sliding block 2821 is protruded from an inner surface of an associated one of the two receiving grooves 2823. Preferably, an outer surface of an associated sliding block 2821 is a spherical surface. In the embodiment, a cross section of the inner surface of each receiving groove 2823 is substantially semicircular. The inner surface of each of the two receiving grooves 2823 of an associated linkage member 282 is provided with at least one sliding block 2821 along an extending direction of an associated receiving groove 2823. In other embodiments, the inner surface of each of the two receiving grooves 2823 is provided with two or more sliding blocks 2821 spaced apart from each other along the extending direction of the associated receiving groove 2823. A middle of the linkage member 282 defines a through hole 2825 along the extending direction of the two receiving grooves 2823.

Outer peripheral walls of the two shafts 281 are rotatably received in the two receiving grooves 2823, respectively. The outer peripheral wall of each of the two shafts 281 is provided with at least one spiral guide groove 2811. When each of the two shafts 281 is received in an associated one of the two receiving grooves 2823, the sliding block 2821 in each of the two receiving grooves 2823 is slidably inserted into an associated spiral guide groove 2811. Preferably, a cross section of an inner surface of each spiral guide groove 2811 is semicircular. An outer surface of the sliding block 2821 is slidably attached to an inner surface of an associated spiral guide groove 2811. Specifically, a rotating cylinder 2812 is fixedly sleeved on a middle of each of the two shafts 281. The rotating cylinder 2812 is a cylinder. The spiral guide groove 2811 is defined on the outer peripheral wall of the rotating cylinder 2812. In the embodiment, an outer peripheral wall of the rotating cylinder 2812 defines one spiral guide groove 2811. In other embodiments, an outer peripheral wall of the rotating cylinder 2812 defines two or more spiral guide grooves 2811. Preferably, a radius of the rotating cylinder 2812 is equal to a radius of the receiving groove 2823, such that an outer peripheral wall of an associated rotating cylinder 2812 is attached to an inner peripheral wall of an associated receiving groove 2823. Two opposite ends of the outer peripheral wall of the rotating cylinder 2812 of each of the two shafts 281 respectively define two annular fastening grooves 2814 along a circumferential direction of thereof. Each of the two fastening grooves 2814 is configured to fasten an associated fixing piece 283. A cross section of a first end 2815 of each of the two shafts 281 is kidney-shaped, and a cross section of a second end 2816 opposite to an associated first end 2815 of each of the two shafts 281 is circular. The first end 2815 of each of the two shafts 281 is configured to couple an associated transmission member 262.

Two opposite ends of each fixing piece 283 are respectively provided with two hooks 2832. A middle of each fixing piece 283 is provided with a fastening hole 2834. Each of the two hooks 2832 can be inserted into an associated one of the two fastening grooves 2814. The second connection frame 284 includes a connection piece 2841 and an overlapping piece 2845 arranged at a middle of one side of the connection piece 2841. The overlapping piece 2845 in an extending direction is perpendicular to the connection piece 2841 in an extending direction. Two opposite ends of the connection piece 2841 respectively define two rotating holes 2842. Two opposite end surfaces of the connection piece 2841 are respectively arranged as two arc surfaces. A middle of the connection piece 2841 defines a through hole 2843. A middle of one end of the overlapping piece 2845 away from the connection piece 2841 defines a connection hole 2846.

The fixing block 286 includes an arc-shaped front surface 2861, a bottom surface, two opposite end surfaces 2862, and two opposite side surfaces. One end of a middle of the front surface 2861 of the fixing block 286 defines a receiving groove 2863. The receiving groove 2863 penetrates the end surface 2862. A bottom surface of the receiving groove 2863 of the fixing block 286 defines a connection hole 28630. A middle of the end surface 2862 of the fixing block 286 facing away from the receiving groove 2863 protrudes a connection piece 2864. The connection piece 2864 defines a through hole. Two opposite sides of the end surface 2862 defined the receiving groove 2863 of the fixing block 286 respectively define two connection holes 2865. The connection hole 2865 does not penetrate the fixing block 286. Two opposite sides of the end surface 2862 arranged the connection piece 2864 of the fixing block 286 respectively define two guide grooves 2867. Each of the two guide grooves 2867 is a circular arc groove. The two guide grooves 2867 respectively penetrate the two opposite sides of the fixing block 286.

In the embodiment, the number of the first shielding mechanism 290 is two, that is, an end of each of the two folding assisting assemblies 24 is provided with an associated shielding mechanism 290. Specifically, the first shielding mechanism 290 includes a plurality of shielding units hinged to each other. The plurality of shielding units are respectively coupled to the connection mechanism 27, the first rotating hinge 252, the second rotating hinge 253, the first connection hinge 254, and the second rotating hinge 257. Preferably, an associated one of the plurality of shielding units, which is located at a middle of each of the two first shielding mechanisms 290, and the second guide rail block 272 of the connection mechanism 27 are made in one piece. The other of the plurality of shielding units, which are correspondingly located on two opposite ends of the associated one of the plurality of shielding units, are coupled to the first connection hinge 254 and the second connection hinge 257, respectively. When the plurality of hinges of the bendable mechanism 25 are relatively rotatable to each other, the plurality of shielding units are also relatively rotatable to each other. The first shielding mechanism 290 is configured to shield sundries, such as dust or water, from entering into the foldable device 22 from a side surface of thereof.

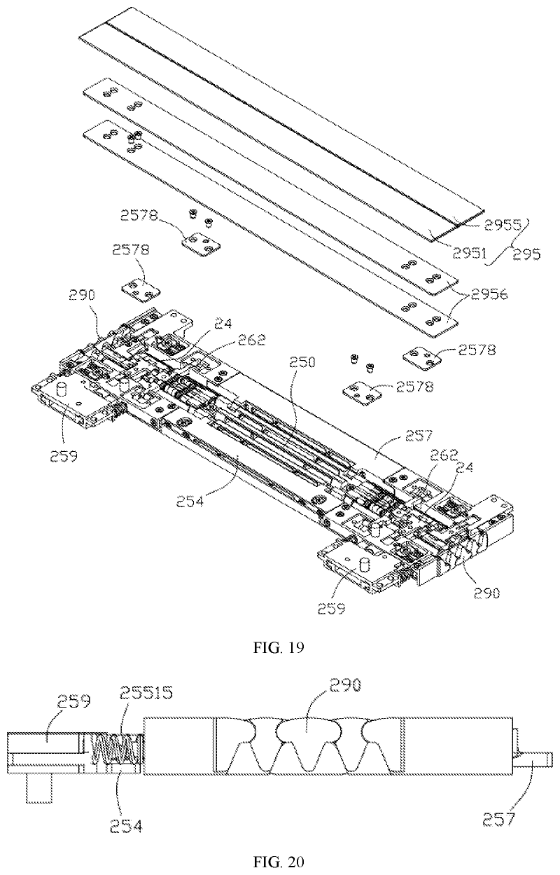

As illustrated in FIG. 18 and FIG. 19, each of the two first shielding mechanisms 290 is a bracelet-like structure formed by the plurality of shielding units, which are sequentially coupled to each other. The plurality of shielding units includes a first shielding unit, a second shielding unit, and a third shielding unit located between the first shielding unit and the second shielding unit. The first shielding unit is coupled to the connection mechanism 27. The second shielding unit is coupled to the first connection hinge 254 and the second connection hinge 257. The third shielding unit is coupled to the first rotating hinge 252 and the second rotating hinge 253. Specifically, the first shielding mechanism 290 includes a middle blocking piece 291 located in a middle of thereof, two connection blocking pieces 292 rotatably coupled to two opposite sides of the middle blocking piece 291, and two fixing blocking pieces 293. Each of the two fixing blocking pieces 293 is rotatably coupled to an associated one of the two connection blocking pieces 292 away from the middle blocking piece 291. Optionally, the middle blocking piece 291 is fixedly coupled to an end of the second guide rail block 272 facing away from the first guiding rail block 271. The two connection blocking pieces 292 are respectively fixedly coupled to the first rotating hinge 252 and the second rotating hinge 253. Two fixing blocking pieces 293 are respectively fixedly coupled to ends of the first connection hinge 254 and the second connection hinge 257. The first shielding unit is the middle shielding piece 291. The second shielding unit is the fixing shielding piece 293. The third shielding unit is the connection shielding piece 292.

Specifically, the middle blocking piece 291 includes a connection part 2911, which is substantially kidney-shaped, and a shielding part 2912 arranged on one side of the connection part 2911. Two opposite ends of one side of the connection part 2911 adjacent to the second guide rail block 272 are respectively provided with two rotating shafts 2914. The opposite ends of the connection part 2911 define two receiving notches around each of the two rotating shafts 2914.

Each connection blocking piece 292 includes a connection part 2921, which is substantially kidney-shaped, a shielding part 2922 arranged on one side of the connection part 2921, and a connection bar 2924 arranged on an end of the shielding part 2922 away from the connection part 2921. The connection part 2921 includes a front surface and two opposite end surfaces, which are arc-shaped surfaces. The connection part 2921 further includes a front surface, which is smoothly coupled to each of the two opposite end surfaces. Two opposite ends of one side of the connection part 2921 facing away from the connection bar 2924 respectively define two receiving grooves. A side surface of the connection part 2921 is formed as an arc surface at each of the two receiving grooves. Two opposite ends of the connection part 2921 respectively define two shaft holes 2925 in air communicating with an associated one of the two receiving grooves. An end of the connection bar 2924 defines a through hole. Each of the two fixing blocking pieces 293 includes a connection part 2931, a shielding part 2932 arranged on one side of the connection part 2931, and a fixing part 2934 arranged on the shielding part 2932. An end surface of the connection part 2931 away from the shielding part 2932 is an arc-shaped surface. An end of the connection part 2931 away from the shielding part 2932 is provided with a rotating shaft 2935 protruding along an axis of the arc-shaped surface. The fixing part 2934 defines a plurality of connection holes 2936.

In assembling of the folding assistance assembly 24, the two connection blocking pieces 292 are respectively located on the opposite sides of the middle blocking piece 291, such that the opposite ends of the middle blocking piece 291 are respectively accommodated in the receiving grooves of the two connection blocking pieces 292, and the two rotating shafts 2914 are respectively inserted into the shaft holes 2925 of the two connection blocking pieces 292. The two fixed blocking pieces 293 are respectively located on one side of the two blocking pieces 292 away from the middle blocking piece 291. The ends of the two fixed blocking pieces 293 provided with the rotating shafts 2935 are respectively accommodated in the receiving grooves of the two connection blocking pieces 292, and the rotating shafts 2935 of the two fixed blocking pieces 293 are respectively inserted into the shaft holes 2925. The second guide rail matching surface 2771 of the second guide rail rod 277 is fitted to the second guide rail curve surface 2722 of the second guide rail block 272, such that one of the two second slide guide rails 2773 of the second guide rail rod 277 is inserted into the second guide groove 2724. The third guide rail block 274 is coupled to the second guide rail block 272. The positioning post 2747 of the third guide rail block 274 is fastened into the connection hole 2727, to allow the other of the two second slide guide rails 2773 of the second guide rail rod 277 to be inserted into the guide groove 2746. The first guide rail matching surface 2751 of the first guide rail rod 275 is fitted to the first guide rail curve surface 2711 of the first guide rail block 271, such that one of the two first slide guide rails 2753 of the first guide rail rod 275 is inserted into the first guide groove 2714. The side of the third guide rail block 274 facing away from the second guide rail block 272 is coupled to the first guide rail block 271. The positioning post 2744 is fastened to the connection hole 2717, and the other of the two first slide guide rails 2753 of the first guide rail rod 275 is inserted into the guide groove 2743. The rotating cylinders 2812 of the two shafts 281 are respectively accommodated in the two receiving grooves 2823 of the linkage member 282. The sliding block 2821 is slidably accommodated in the associated spiral guide groove 2811. The two hooks 2832 of each of the two groups of the fixing pieces 283 can be correspondingly inserted into the associated fastening grooves 2814. At this time, the hooks 2832 of each of the two groups of the fixing pieces 283 are aligned with the through holes 2825 of the linkage member 282. Each of the first connection frame 264 and the second connection frame 284 is located on a side of an associated one of the two groups of fixing pieces 283 facing away from the linkage member 282, such that the first ends 2815 of the two shafts 281 are respectively inserted into the two through holes 2643 of the first connection frame 264, and the second ends 2816 are respectively inserted into the two through holes 2843 of the second connection frame 284. The connection column 287 is inserted into the through hole 2843 of the second connection frame 284, the fastening hole 2834 of the fixing piece 283, the through hole 2825 of the linkage member 282, and the through hole 2643 of the first connection frame 264 in sequence. The first ends 2815 of the two shafts 281 are fixedly inserted into the inner cavities of the connection cylinders 2624 of the two transmission members 262, and then are inserted into the two connection holes 2717 of the first guide rail block 271. At this time, the overlapping piece 2645 of the first connection frame 264 overlaps the front surface of the first guide rail block 271. The connection hole 2646 is aligned with the positioning hole 2719. The notches 2625 of the two transmission members 262 are respectively aligned with the two notches 2718 of the first guide rail block 271. The locking member passes through the connection hole 2646 and is locked to the positioning hole 2719. The second ends 2816 of the two shafts 281 are respectively inserted into the two connection holes 2865 of the fixing block 286. The overlapping piece 2845 is accommodated in the accommodating groove 2863. The locking member passes through the connection hole 2846 and is locked to the connection hole 28630.

At this time, the connection cylinders 2624 of the two transmission members 262 are respectively fixedly coupled to the first ends 2815 of the two shafts 281. One of the transmission members 262 rotates along an associated one of the two shafts 281 to drive the associated one of the two shafts 281 to rotate. The associated one of the two shafts 281 rotates to allow an associated sliding block 2821 to be slidable in an associated spiral guide groove 2811, such that the linkage member 282 is slidable along the connection column 287. The linkage member 282 is slidable to drive the other of the transmission members 262 to rotate, thus realizing the linkage of the transmission members 262. That is, the two transmission members 262 synchronously rotate towards each other in opposite directions or rotate away from each other in the trailing directions. The two transmission members 262 synchronously rotate towards each other in the opposite directions referring that ends of the two transmission members 281 away from an associated one of the two shafts 281 are relatively close together. The two transmission members 262 synchronously rotate away from each other in the trailing directions referring that the ends of the two transmission members 262 away from the associated one of the associated one of the two shafts 281 are relatively far away. The first sliding rail 2753 of the first guide rail rod 275 is slidably received in the first guide groove 2714 and the guide groove 2743. The guide rail matching surface 2751 is slidably fitted to the first guide rail curve surface 2712. The first clamping part 2752 slidably abuts against the first clamping matching part 2716. The first clamping part 2752 has a movable dampening relative to the first clamping matching part 2716. The second sliding rail 2773 of the second guide rail rod 277 is slidably received in the second guide groove 2774 and the guide groove 2746. The second guide rail matching surface 2771 is slidably fitted to the second guide rail curve surface 2722. The second clamping part 2772 elastically abuts against the second clamping matching part 2726. The second fitting part 2772 has a movable damping when sliding relative to the second clamping matching part 2726. At this time, the first guide rail rod 275 in a length direction is substantially parallel to the second guide rail rod 277 in a length direction.

As illustrated in FIG. 4 to FIG. 6, the shielding mechanism 29 is arranged on an inside of the bendable mechanism 25. The shielding mechanism 29 is coupled to the connection mechanism 27. When the bendable mechanism 25 is folded, the connection mechanism 27 can drive the shielding mechanism 29 to slide relative to the bendable mechanism 25. Specifically, the first shielding mechanism 290 of the shielding mechanism 29 is arranged at two opposite ends of the bendable mechanism 25. The second shielding mechanism 295 is arranged on a back surface of the bendable mechanism 25. The middle blocking piece 291 of the first shielding mechanism 290 is fixedly coupled to the connection mechanism 27. The two connection blocking pieces 292 and the two fixing blocking pieces 293 are coupled to the bendable mechanism 25. The second shielding mechanism 295 is coupled to the connection mechanism 27. When the bendable mechanism 25 is folded, the connection mechanism 27 can drive the second shielding mechanism 295 to slide relative to the bendable mechanism 25, and the first shielding mechanism 290 is folded with the bendable mechanism 25.

The shielding mechanism 29 covers at least the middle hinge 250, that is, the second shielding mechanism 295 covers at least the middle hinge 250. Specifically, the second shielding mechanism 295 includes a first shielding member 2951 and a second shielding member 2955. The intermediate hinge 251 includes a first part and a second part, which are arranged side by side. The first shielding member 2951 covers at least the first part of the intermediate hinge 251 and the second rotating hinge 253. The second shielding member 2955 covers at least the second part of the intermediate hinge 251 and the first rotating hinge 252. In the embodiment, the first shielding member 2951 and the second shielding member 2955 are both strip-shaped shielding plates. Since a structure of the first shielding member 2951 is the same as a structure of the second shielding member 2955, only the first shielding member 2951 will be described in further details. The first shielding member 2951 includes a rectangular cover plate 2952 and a flange 2953 arranged on an edge of a front surface of the cover plate 2952. An accommodation space 2954 is formed surrounded by the cover plate 2952 and the flange 2953. A connection piece 2956 is received in the accommodation space 2954 of the first shielding member 2951. The first shielding member 2951 is fixedly coupled to the first guide rail rod 275 by the connection piece 2956. Specifically, two opposite ends of the connection piece 2956 respectively define a plurality of connection holes 2957. The second shielding member 2955 also includes a rectangular cover plate and a flange arrange on an edge of a front surface of the cover plate. The second shielding member 2955 is also fixedly coupled to the second guide rail rod 277 by a connection piece 2956.

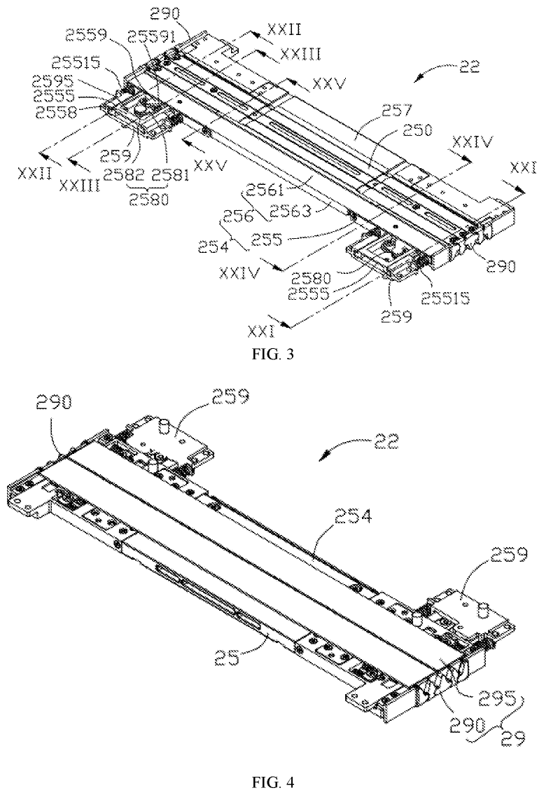

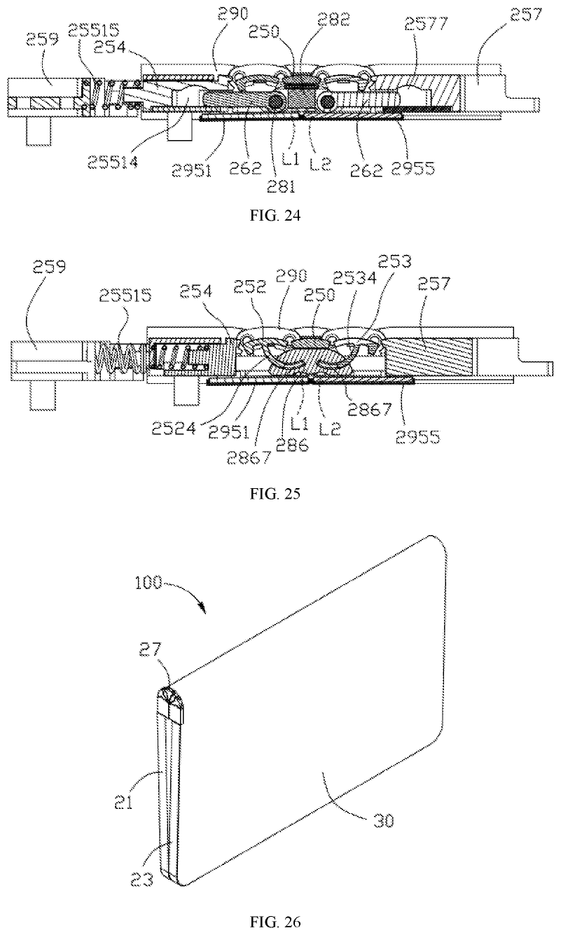

As illustrated in FIG. 3 to FIG. 25, in assembling of the foldable device 22, the two folding assisting assemblies 24 are respectively located on the two opposite ends of the back surface of the intermediate hinge 251, such that the through hole of the connection piece 2864 of the fixing block 286 of each of the two folding assisting assemblies 24 is correspondingly aligned with an associated one of the connection posts 2512 of the intermediate hinge 251, and the positioning hole 2729 of the second guide rail block 272 is correspondingly aligned with the countersunk hole 2514. Two screws are respectively inserted into the two through holes of the two connection pieces 2864 of the two folding assisting assemblies 24, and are locked in the connection holes of an associated two of the connection columns 2512. Two locking members are correspondingly inserted into the two countersunk holes 2514 located at two ends of the intermediate hinge 251, and are locked in the positioning holes 2729 of the two folding assisting assemblies 24. The first rotating hinge 252 and the second rotating hinge 253 are respectively located on the two opposite sides of the intermediate hinge 251. The two second arc-shaped guiding plates 2524 of the first rotating hinge 252 are respectively inserted into the two guide grooves 2867 of the two folding assisting assemblies 24. The two second arc-shaped guiding plates 2534 of the second rotating hinge 253 are respectively inserted into the two guide grooves 2867 of the two folding assisting assemblies 24. The four connection bars 2924 of the four connection blocking pieces 292 of the first shielding mechanism 290 of the two folding assisting assemblies 24 are correspondingly arranged on the two positioning blocks 2526 located at the two opposite ends of the first rotating hinge 252 and the two positioning blocks 2536 located at the opposite ends of the second rotating hinge 253. The plurality of locking members are respectively inserted into the through holes of the connection bars 2924 and locked in the corresponding connection holes 2527, 2537. The first connection hinge 254 and the second connection hinge 257 are respectively located on the opposite sides of the middle hinge 250. The first guide rail rods 275 located on one side of the two folding assisting assemblies 24 are respectively inserted into the sliding guide grooves 2556 of the first connection hinge 254, such that the end of each of the first guide rail rods 275 is rotatably coupled to the first end of the first connection rod 2581 of an associated connection rod 2580, that is, the locking member is inserted into the connection hole 2757 located at the end of the extension piece 2756 and coupled to the through hole 2583 located at the first end of the first connection rod 2581. The second guide rail rods 277 located on the other side of the two folding assisting assemblies 24 are respectively inserted into the second sliding guide grooves 2570 of the second connection hinge 257. The two positioning pieces 25760 on the first connection hinge 254 can be correspondingly pushed by the elastic pieces 25765 to allow the fastening block 25761 to be fastened into an associated positioning opening 2758. Since the two positioning pieces 25760 on the second connection hinge 267 are correspondingly pushed by the elastic pieces 25765 to allow the fastening block 25761 to be fastened into the associated positioning opening 2758, the foldable device 22 may be in the unfolded state.

The sliding guide rod 2623 of the transmission member 262 on one side of the two folding assisting assemblies 24 is accommodated in the transmission groove 25514 on the first connection hinge 254. The two transmission grooves 25514 are respectively covered by the two cover plates 25513, which are fixed by the plurality of the locking members. At this time, the sliding guide rod 2623 can slide along the arc surface of the transmission groove 25514. The sliding guide rod 2623 of the transmission member 262 on the other side of the two folding assisting assemblies 24 is accommodated in the transmission groove 2577 on the second connection hinge 257. The two transmission grooves 2577 are respectively covered by the two cover plates 2578, which are fixed by the plurality of the locking members. At this time, the sliding guide rod 2623 can slide along the arc surface of the transmission groove 2577. The two fixing blocking pieces 293 of the first shielding mechanism 290 of each the two folding assisting assemblies 24 are respectively fixed to the ends of the first connection hinge 254 and the second connection hinge 257, that is, the fixing parts 2934 of the two fixing blocking pieces 293 are respectively fastened to the fixing groove 25518 of the first connection hinge 254 and the fixing block 25725 coupled to the second connection hinge 257, and the locking members are inserted into the connection holes 2936, thereby locking the two fixing blocking pieces 293 with the first connection hinge 254 and the second connection hinge 257, respectively. The two lugs 25516 of the first connection hinge 254 correspond to the first arc-shaped guide plates 2522 of the first rotating hinge 252. The two lugs 25723 of the second connection hinge 257 correspond to the first arc-shaped guide plates 2532 of the second rotating hinge 253. The second shielding mechanism 295 is mounted on the two folding assisting assemblies 24, that is, the first shielding member 2951 is fixedly coupled to the first guide rail rod 275, and the second shielding member 2955 is fixedly coupled to the second guide rail rod 277. Specifically, one of the two connection pieces 2956 covers the back surface of the two first guide rail rods 275. The plurality of locking numbers are respectively inserted into the connection holes 2957 of the two connection pieces 2956 and locked to an associated one of the fixing holes 2755. Each of the two first shielding members 2951 is sleeved and fixed to an associated one of the two connection pieces 2956. The other of the two connection pieces 2956 covers the back surface of the two second guide rail rods 277. The plurality of locking numbers are respectively inserted into the connection holes 2957 of the connection piece 2956 and locked to the associated one of the fixing holes 2775. Each of the two second shielding pieces 2955 sleeved and fixed to an associated one of the two connection pieces 2956. The second shielding mechanism 295 covers the back surface of the foldable device 22, thus preventing dust and other impurities from entering the foldable device 22 from the back surface of thereof. At this time, when the bendable mechanism 25 is folded, the shielding mechanism 29 rotates around the virtual axis relative to the bendable mechanism 25. Specifically, the first shielding member 2951 of the second shielding mechanism 295 rotates around the first virtual axis L1 relative to the bendable mechanism 25. The second shielding member 2955 rotates around the second virtual axis L2 relative to the bendable mechanism 25.

Since the linkage mechanism 28 is coupled to the middle hinge 250, when the connection hinge located on one side of the middle hinge 250 rotates, the linkage mechanism 28 can drive the connection hinge located on the other side of the middle hinge 250 to rotate. Specifically, when the first connection hinge 254 rotates, the linkage mechanism 28 can drive the second connection hinge 257 to rotate synchronously.

Preferably, one end of one of the two transmission members 262 of the transmission mechanism 26 is rotatably coupled to the middle hinge 250, and the other end is slidably coupled to an associated one of the connection hinges. Specifically, one end of an associated one of the two transmission members 262 on one side of each of the two folding assisting assemblies 24 is rotatably coupled to the middle hinge 250, and the other end of the associated one of the two transmission members 262 on one side of each of the two folding assisting assemblies 24 is rotatably and slidably coupled to the first connection hinge 254. One end of an associated one of the two transmission members 262 on the other side of each of the two folding assisting assemblies 24 is rotatably coupled to the middle hinge 250, and the other end of the associated one of the two transmission members 262 on the other side of each of the two folding assisting assemblies 24 is rotatably and slidably coupled to the second connection hinge 257.

Preferably, the connection mechanism 27 is rotatably coupled to the middle hinge 250 and slidable relative to an associated one of the connection hinges. Specifically, one end of one of the guide rail rods of the connection mechanism 27 is rotatably coupled to the middle hinge 250, and the other end is slidably coupled to the associated one of the connection hinges. Furthermore, the connection mechanism 27 is rotatably coupled to the middle hinge 250 around the virtual axis. Specifically, the first guide rail rod 275 of each of the two folding assisting assemblies 24 is rotatably coupled to the middle hinge 250 along the first virtual axis L1, and the other end is slidably coupled to the first connection hinge 254. The second guide rail rod 277 of each of the two folding assisting assemblies 24 is rotatably coupled to the middle hinge 250 along the second virtual axis L2, and the other end is slidably coupled to the second connection hinge 257.

The transmission mechanism 26 of each of the two folding assisting assemblies 24 is rotatably coupled to the middle hinge 250 around the two shafts 281. The connection mechanism 27 is rotatably coupled to the middle hinge 250 around at least one virtual axis. The shafts 281 are staggered from the at least one virtual axis. Specifically, the two transmission members 262 of the transmission mechanism 26 are coupled to the middle hinge 250 by the two shafts 281, which are arranged in parallel and at interval. The at least one virtual axis include a first virtual axis L1 and a second virtual axis L2, which are arranged in parallel and at interval. The first guide rail rod 275 is rotatably coupled to the middle hinge 250 around the first virtual axis L1. Furthermore, the first guide rail rod 275 rotates along the first virtual axis L1 relative to the first guide rail block 271. The second guide rail rod 277 is rotatably coupled to the middle hinge 250 around the second virtual axis L2. Furthermore, the second guide rail rod 277 rotates along the second virtual axis L2 relative to the second guide rail block 272. Specifically, the first virtual axis L1 is the axis of the first guide rail curve surface 2712. The second virtual axis L2 is the axis of the second rail curve surface 2722. The shafts 281, the first virtual axis L1, and the second virtual axis L2 are arranged in parallel and at interval.

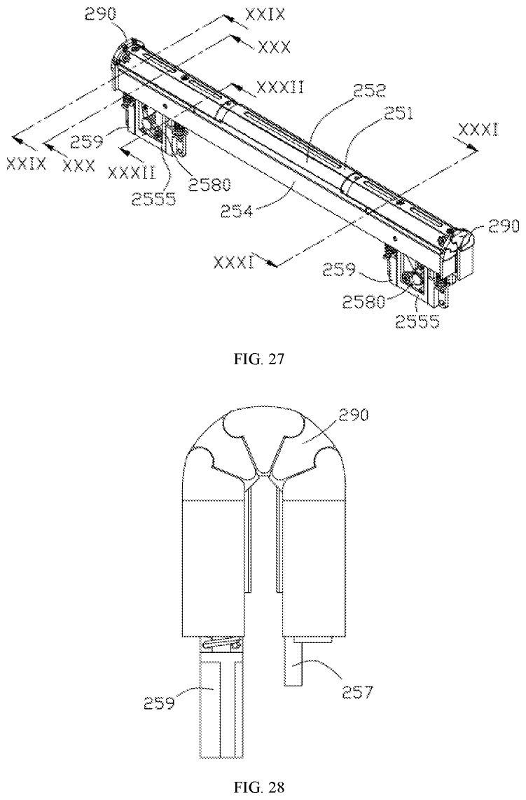

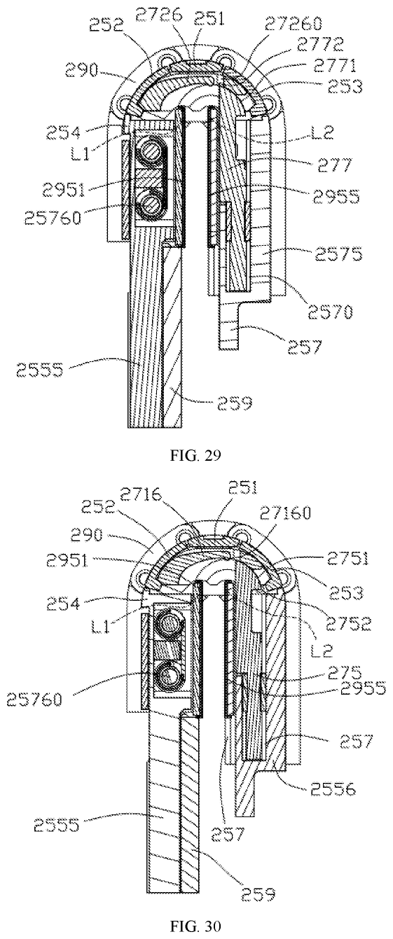

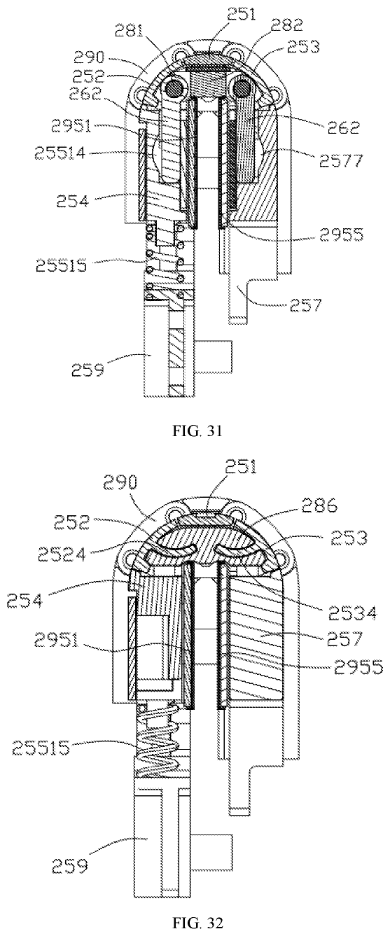

As illustrated in FIG. 26 to FIG. 32, when the foldable device 22 is folded, the first connection hinge 254 is rotated toward the second connection hinge 257. The two first guide rail rods 275 are respectively slidable in the two first guide grooves 2556 of the first connection hinge 254. Each of the two first guide rail rods 275 slidably abuts against an associated positioning member 25760 to slide away from the first guide rail rod 275. The elastic member 25765 is elastically deformed, such that the positioning member 25760 of the fastening block 25761 is separated from an associated positioning opening 2758. The two transmission rods 2621 are correspondingly slidable in the transmission grooves 25514 of the first connection hinge 254. Since the two transmission parts 262 of each of the two folding assisting assemblies 24 are coupled by the linkage mechanism 28, when the transmission rod 2621 coupled between the first connection hinge 254 and the linkage mechanism 28 rotates, an associated one of the shafts 281 is driven by the transmission rod 2621 coupled between the first connection hinge 254 and the linkage mechanism 28 to rotate, the associated one of the shafts 281 drives the other of the shafts 281 on an opposite side to the associated one of the shafts 281 to rotate via the linkage member 282, the other of the shafts 281 drives the other of the two transmission rods 2621 coupled between the second connection hinge 257 and the linkage mechanism 28 to rotate, thus allowing the second connection hinge 257 to rotate toward the first connection hinge 254 synchronously. The second connection hinge 257 drives the second guide rail rod 277 to slide in the second sliding guide groove 2570. The second guide rail rod 277 slidably abuts against an associated positioning member 25760 to slide away from the second guide rail rod 275. The elastic member 25765 is elastically deformed. Such that the fastening block 25761 of the positioning member 25760 is separated from an associated positioning opening 2778, and the two second guide rail rods 277 of each of the two folding assisting assemblies 24 are also close to each other, then thereby realizing the linkage bending of the foldable device 22.

In a folding process, the extension piece 2756 of the first guide rail rod 275 drives the first end of the first connection rod 2581 to rotate relative to the extension piece 2756, and drives the second end of the first connection rod 2581 to rotate relative to the second connection rod 2582, such that the first connection rod 2581 moves away from the second stopper 2559 until the first connection rod 2581 abuts against the first stopping surface 25581 of the stopping bar 2558 and the first stopper 2595. The connection hinges rotate relative to the middle hinge 250 around the virtual axes. Specifically, the first connection hinge 254 is rotatable relative to the middle hinge 250 around the first virtual axis L1, and the first connection hinge 254 is slidable relative to the middle hinge 250. The second connection hinge 257 is rotatable relative to the middle hinge 250 around the second virtual axis L2, and the second connection hinge 257 is slidable relative to the middle hinge 250. The first guide rail matching surface 2751 of the first guide rail rod 275 is slidably fitted to the first guide rail curve surface 2712. The first clamping part 2752 of the first guide rail rod 275 slidably abuts against the first clamping matching part 2716 to allow the first clamping matching part 2716 to be elastically deformed. A movable damping is formed between the first clamping part 2752 and the first clamping matching part 2716 until the first clamping part 2752 is broke free from the fastening strip 27162. At the same time, the second guide rail fitting surface 2771 of second guide rail rod 277 is slidably fitted on the second guide rail curve surface 2722, and the second clamping part 2772 of the second guide rail rod 277 slidably abuts against the second clamping matching part 2726, such that the second clamping matching part 2726 is elastically deformed, and a movable damping is formed between the second clamping part 2772 and the second clamping matching part 2726 until the second clamping part 2772 is engaged with the fastening groove 27262, then thereby positioning the bendable mechanism 25 to maintain the folded state. The two fixing blocking pieces 293 of each of the two first shielding mechanisms 290 move with the first connection hinge 254 and the second connection hinge 257 to drive the two connection blocking pieces 292 to rotate synchronously. The two connection blocking pieces 292 drive the first rotating hinge 252 and the second rotating hinge 253 to rotate synchronously. The second arc-shaped guiding plates 2524 of the first rotating hinge 252 is slidable in an associated one of the guide grooves 2867, and the second arc-shaped guiding plates 2534 of the second rotating hinge 253 is slidable in an associated one of the guide grooves 2867. The two first arc-shaped guiding plates 2522 of the first rotating hinge 254 are slidably contacted with an associated protrusion pieces 25516 of the first connection hinge 254, and the two first arc-shaped guiding plates 2532 of the second rotating hinge 253 are slidably contacted with an associated protrusion pieces 25723 of the second connection hinge 257, thus realizing the synchronous bending of the bendable mechanism 25.

Preferably, the first shielding member 2951 of the second shielding mechanism 295 rotates with the first guide rail rod 257 relative to the middle hinge 251, that is, the first shielding member 2951 rotates along the first virtual axis L1, the second shielding member 2955 rotates along the second virtual axis L2. The first virtual axis L1 and the second virtual axis L2 are arranged in parallel and at interval. The virtual axes of the connection mechanism 27 and the virtual axes of the shielding mechanism 29 are both located in the shielding mechanism 29. The virtual axes of the connection mechanism 27 are the same as the virtual axes of the shielding mechanism 29. Specifically, the first virtual axis L1 is located in the first shielding member 2951. The second virtual axis L2 is located in the second shielding member 2955. Preferably, the virtual axes are located on a back surface of the second shielding mechanism 295 or adjacent to the back surface of the second shielding mechanism 295. Specifically, the first virtual axis L1 is located at or adjacent to the back surface of the first shielding member 2951, and the second virtual axis L2 is located at or adjacent to the back surface of the second shielding member 2955. The first virtual axis L1 and the second virtual axis L2 are close to the back surface of the second shielding mechanism 295. In the unfolding and folding processes, the closer to the back surface of the second shielding mechanism 295 the virtual axes are, the smaller length difference of the back surface of the second shielding mechanism 295 is, such that the back surface of the second shielding mechanism 295 will not be subjected to tension or compression.

The virtual axes of the connection mechanism 27 are close to the middle hinge 250 and away from the connection hinges. Specifically, the first guide rail rod 275 rotates around the first virtual axis L1 relative to the middle hinge 250, and the first virtual axis L1 is close to the middle hinge 250 and away from the first connection hinge 254. The second guide rail rod 277 rotates around the second virtual axis L2 relative to the middle far 250, and the second virtual axis L2 is close to the middle hinge 250 and away from the second connection hinge 257.

Preferably, a sliding track of the transmission mechanism 26 relative to the connection hinges is arc-shaped, that is, a sliding track between an associated one of the transmission members 262, which is coupled to the first connection hinge 254, and the first connection hinge 254 is a bottom surface of the transmission groove 25514, and a sliding track between an associated one of the transmission members 262, which is coupled to the second connection hinge 257, and the second connection hinge 257 is a bottom surface of the transmission groove 2577.

Optionally, the first clamping part 2752 is located on the first guide rail matching surface 2751. The first clamping matching part 2716 is located on the first guide rail curve surface 2712. When the bendable mechanism 25 is in the unfolded state, the first clamping matching part 2716 is fastened to the first clamping part 2752. When the bendable mechanism 25 is folded, the first clamping part 2752 overcomes a resistance of the first clamping matching part 2716 and breaks away from the first clamping matching part 2716.

When the connection hinges are movable relative to the middle hinge 250, the transmission mechanism 26 slides relative to the connection hinges. Specifically, when the first connection hinge 254 rotates and slides relative to the middle hinge 250, an associated one of the transmission members 262 coupled between the first connection hinge 254 and the middle hinge 250 slides relative to the first connection hinge 254. When the second connection hinge 257 rotates and slides relative to the middle hinge 250, an associated one of the transmission members 262 coupled between the second connection hinge 257 and the middle hinges 250 slides relative to the second connection hinge 257.

The sliding track of the transmission mechanism 26 relative to the connection hinges is different from a sliding track of the connection mechanism 27 relative to the connection hinges. Specifically, a sliding track of an associated transmission member 262 of the transmission mechanism 26 relative to the first connection hinge 254 or the second connection hinge 257 is different from that of the first guide rail rod 275 of the connection mechanism 27 relative to the first connection hinge 254 or that of the second guide rail rod 277 of the connection mechanism 27 relative to the second connection hinge 257.

Preferably, when the bendable mechanism 25 is folded, the transmission mechanism 26 is slidable relative to the connection hinges. A slide vector of the transmission mechanism 26 relative to an associated one of the connection hinges includes a first slide component and a second slide component. The first slide component faces away from or toward the middle hinge 250, and the second slide component is perpendicular to the first slide component. Specifically, a slide vector of the transmission member 262, which coupled to the first connection hinge 254, relative to the first connection hinge 254 includes a first slide component facing away from or pointing to the middle hinge 250 and a second slide component perpendicular to the first slide component.

Preferably, a movement of each of the connection hinges relative to the middle hinge 250 includes a rotating movement of an associated one of the connection hinges relative to the middle hinge 250 and a sliding movement of the associated one of the connection hinges relative to the middle hinge 250. The associated one of the connection hinges slides relative to the middle hinge 250 while rotating relative to the middle hinge 250. Specifically, a movement of the first connection hinge 254 relative to the middle hinge 250 includes a rotating movement of the first connection hinge 254 relative to the middle hinge 250 and a sliding movement of the first connection hinge 254 relative to the middle hinge 250. The first connection hinge 254 slides relative to the middle hinge 250 while rotating relative to the middle hinge 250. A movement of the second connection hinge 257 relative to the middle hinge 250 includes a rotating movement of the second connection hinge 257 relative to the middle hinge 250 and a sliding movement of the second connection hinge 257 relative to the middle hinge 250. The second connection hinge 257 slides relative to the middle hinge 250 while rotating relative to the middle hinge 250.

When the bendable mechanism 25 is folded, the connection mechanism 27 slides in a first direction relative to an associated one of the connection hinges until the first stopper 2595 is limited by the connection mechanism 27 in a second direction. The second direction is opposite to the first direction. Specifically, the first guide rail rod 275 slides in the first direction relative to the first connection hinge 254 until the first stopper 2595 is limited by the first guide rail rod 275 in the second direction.

Optionally, when the bendable mechanism 25 is folded, a movement direction of the first end of the second connection rod 2582 relative to an associated one of the connection hinges is opposite to a movement direction of the first end of the first connection rod 2581 relative to the associated one of the connection hinges. Specifically, the first end of the second connection rod 2582 moves relative to the first connection hinge 254 in a direction opposite to that in which of the first end of the first connection rod 2581 moves relative to the second connection hinge 257.

Optionally, when the bendable mechanism 25 is folded, the first end of the first connection rod 2581 moves relative to an associated one of the connection hinges by a distance greater than that by which the second connection rod 2582 moves relative to the associated one of the connection hinges.

Optionally, during the folding of the bendable mechanism 25, an angle formed between the first connection rod 2581 and the second connection rod 2582 increases as curvature of the bendable mechanism 25 increases.

In other uses, the second connection hinge 257 can be rotated toward the first connection hinge 254. The two second guide rail rods 277 are respectively slidable in the two second sliding guide grooves 2570 of the second connection hinge 257. Each of the two second guide rail rods 277 slidably abuts against an associated positioning member 25760 to slide away from the associated one of the two second guide rail rods 277. The elastic member 25765 is elastically deformed to allow the fastening block 25761 of the positioning member 25760 to be separated from an associated positioning opening 2778. The two transmission rods 2621 slide in the transmission groove 2577 of the second connection hinge 257. Since the two transmission members 262 of each of the folding assisting assemblies 24 are coupled to each other by the linkage mechanism 28, when an associated one of the two transmission rods 2621 coupled to the second connection hinge 257 and the linkage mechanism 28 rotates, the associated one of the two transmission rods 2621 can drive an associated one of the two shafts 281 to rotate, the associated one of the two shafts 281 drives the other of the two shafts 281 opposite to the associated one of the two shafts 281 by the linkage member 282, and the other of the two shafts 281 rotates drives the other of the transmission rods 2621 coupled between the first connection hinge 254 and the linkage mechanism 28 to rotate. Such that the first connection hinge 254 rotates synchronously toward the second connection hinge 254, the first connection hinge 254 drives the first guide rail rod 257 to slide in the first sliding groove 2556, the first guide rail rod 257 slidably abuts against an associated positioning member 25760 to slide away from the first guide rail rod 257, the elastic member 25765 is elastically deformed to allow the fastening block 25761 of the positioning member 25760 to separated from an associated positioning opening 2758, and the two first guide rail rods 275 of each of the two folding assisting assemblies 24 are also close to each other, then thereby realizing the linkage bending of the foldable device 22.

In other uses, the first connection hinge 254 and the second connection hinge 257 can also rotate to each other and move toward to each other in the opposite directions. Since the two transmission members 262 of each of the two folding assisting assemblies 24 are coupled by the linkage mechanism 28, the first connection hinge 254 and the second connection hinge 257 together drive the two transmission members 262 of each of the two folding assisting assemblies 24 to rotate to each other and move toward to each other in the opposite directions, and thereby driving the two shafts 281 to rotate. Such that the two transmission members 262 are close to each other, and the first connection hinge 254 and the second connection hinge 257 are synchronously close to each other to allow the foldable device 22 to be folded.

When the foldable device 22 changes from the folded state to the unfolded state, the first connection hinge 254 is rotated away from the second connection hinge 257. The two first guide rail rods 275 are respectively slidable in the two first sliding guide grooves 254 of the first connection hinge 254 to abut against the positioning member 25760, and thereby sliding away from an associated first guide rail rod 275. The elastic member 25765 is elastically deformed until the fastening block 25761 of the positioning member 25760 is fastened into an associated positioning opening 2758. At the same time, the two transmission rods 2621 correspondingly slide in the two transmission grooves 25514 of the first connection hinge 254. Since the two transmission members 262 of each of the two folding assisting assemblies 24 are coupled by the linkage mechanism 28, when an associated one of the two transmission rods 2621 coupled to the first connection hinge 254 and the linkage mechanism 28 rotates, the associated one of the two transmission rods 2621 can drive an associated one of the two shafts 281 to rotate, the associated one of the two shafts 281 drives the other of the two shafts 281 opposite to the associated one of the two shafts 281 by the linkage member 282, and the other of the two shafts 281 rotates drives the other of the transmission rods 2621 coupled between the first connection hinge 254 and the linkage mechanism 28 to rotate. Such that the second connection hinge 257 rotates synchronously away from the first connection hinge 254, the second connection hinge 257 drives the second guide rail rod 277 to slide in the second sliding groove 2570, the second guide rail rod 277 slidably abuts against an associated positioning member 25760 to slide away from the second guide rail rod 275, the elastic member 25765 is elastically deformed to allow the fastening block 25761 of the positioning member 25760 to separated from an associated positioning opening 2778, and the two second guide rail rods 277 of each of the two folding assisting assemblies 24 are also away from each other, then thereby realizing the linkage unfolding of the foldable device 22.

In an unfolded process, the extension piece 2756 of the first guide rail rod 275 drives the first end of the first connection rod 2581 to rotate relative to the extension piece 2756. The second end of the first connection rod 2581 rotates relative to the second end of the second connection rod 2582. Such that the first connection rod 2581 is away from the first stopper 2595 and the first stopping surface 25581 and is close to the second position limiting part 2559 until the first connection rod 2581 fits the second stopping surface 25591. The elastic member 25765 abuts against the positioning member 25760 to slide until the fastening block 25761 is fastened to an associated positioning opening 2758, 2778, thus positioning the foldable device 22 to maintain the unfolded state. The first guide rail matching surface 2751 of the first guide rail rod 275 slidably fits to the first guide rail curve surface 2712 of the second stopper 2559, and the first clamping part 2752 of the first guide rail rod 275 slidably abuts against the first clamping matching part 2716, such that the first clamping matching part 2716 is elastically deformed until the first clamping part 2752 is fastened to the fastening strip 27162. At the same time, the second guide rail matching surface 2771 of the second guide rail rod 277 is slidably fitted to the second guide rail curve surface 2722, and the second clamping part 2772 of the second guide rail rod 277 slidably abuts against the second clamping matching part 2726, such that the second clamping matching part 2726 is elastically deformed until the second clamping part 2772 is fastened to the matching groove 27262, and the foldable device 22 is kept in the unfolded state. The two fixing blocking pieces 293 of each of the first shielding mechanisms 290 rotate with the first connection hinge 254 and the second connection hinge 257 to drive the two connection blocking pieces 292 to rotate synchronously. The two connection blocking pieces 292 drive the first rotating hinge 252 and the second rotating hinge 253 to rotate synchronously and move away from each other. The second arc-shaped guiding plates 2524 of the first rotating hinge 252 slides in an associated guide groove 2867, and the second arc-shaped guiding plates 2534 of the second rotating hinge 253 slides in an associated guide groove 2867, thus realizing the synchronous unfolding of the bendable mechanism 25. The first shielding member 2951 of the second shielding mechanism 295 rotates with the first guide rail rod 257 relative to the middle hinge 251. The second shielding member 2955 rotates with the second guide rail rod 277 relative to the middle hinge 251 until the first shielding member 2951 and the second shielding member 2955 are in an unfolded state.

In other uses, the second connection hinge 257 can be rotated away from the first connection hinge 254 in the trailing directions, and the two second guide rail rods 277 respectively slide in the two second sliding guide groove 2570 of the second connection hinge 257 to abut against the positioning member 25760 to slide away from an associated second guide rail rod 277. The elastic member 25765 is elastically deformed until the fastening block 25761 of the positioning member 25760 is locked into an associated positioning opening 2778. The two transmission rods 2621 are slidable in the transmission grooves 2577 of the second connection hinge 257. Since the two transmission members 262 of each of the two folding assisting assemblies 24 are coupled by the linkage mechanism 28, when one of the transmission rods 262 coupled between the second connection hinge 257 and the linkage mechanism 28 rotates, an associated one of the shafts 281 is driven by the transmission rod 262 coupled between the second connection hinge 257 and the linkage mechanism 28 to rotate, the associated one of the shafts 281 drives the other of the shafts 281 on an opposite side to the associated one of the shafts 281 to rotates via the linkage member 282, the other of the shafts 281 drives the other of the two transmission rods 2621 coupled between the first connection hinge 254 and the linkage mechanism 28 to rotate, and the other of the two transmission rods 2621 drives the first connection hinge 254 to rotate away from the second connection hinge 254.

In other uses, the first connection hinge 254 and the second connection hinge 257 can also rotate to each other and move away from each other in the trailing directions. Since the two transmission members 262 of each of the two folding assisting assemblies 24 are coupled by the linkage mechanism 28, the first connection hinge 254 and the second connection hinge 257 together drive the two transmission members 262 of each of the two folding assisting assemblies 24 to rotate to each other and move away from each other in trailing directions, and thereby driving the two shafts 281 to rotate. Such that the two transmission members 262 move away from each other, and the first connection hinge 254 and the second connection hinge 257 are synchronously move away from each other to allow the foldable device 22 to be unfolded.

When the foldable device 22 is in the unfolded state, the first connection rod 2581 can be fitted to the second stopping surface 25591 of the second stopper 2559, thus preventing collapse of the sliding member 259 on the lug 2555 when the foldable device 22 falls, and thereby avoiding arching and damage to the flexible member 30 fixedly coupled to the sliding member 259. When the foldable device 22 is in the folded state, the first connection rod 2581 can abut against the first stopping surface 25581 of the stopping bar 2558 and the first stopper 2595, thus preventing the collapse of the sliding member 259 on the lug 2555 when the foldable device 22 falls, and thereby avoiding the arching and damage to the flexible member 30 fixedly coupled to the sliding member 259.

As illustrated in FIG. 1 to FIG. 4 and FIG. 11 to FIG. 14, installed foldable device 22 is located between the first frame 21 and the second frame 23. The two lugs 2555 of the first connection hinges 254 are respectively received in the first frame 21, and the sliding member 259 located in the first frame 21 is fixedly coupled to the first frame 21. The connection frame 256 of the first connection hinge 254 and the mounting frame 255 can slide relative to each other in a direction perpendicular to a bending axis of the middle hinge 250. The first elastic member 2553 generates an elastic force for pulling the connection piece 2563 of the connection frame 256 to one side away from the middle hinge 250, and the second elastic member 25515 generates an elastic force for pulling the sliding member 259 away from the first connection hinge 254. Optionally, the first elastic member 2553 and the second elastic member 25515 are both pre-compressed and then installed in corresponding positions. The front surface of the foldable device 22 is coplanar with the front surface of the first frame 21 and the surface front of the second frame 23. A gap is formed between the connection plate 2561 and the mounting frame 255 along the direction perpendicular to the bending axis of the foldable device 22. The foldable device further includes a supporting sheet 50. One end of the supporting sheet 50 is fixed to the second frame 23 and the other end is fixed to the connection plate 2561. Parts between the two ends of the supporting sheet 50 cover parts of the foldable device 22 and can slide relative to the parts of the foldable device 22. Optionally, the first connection hinge 254, the middle hinge 250, and the second connection hinge 257 are covered by the parts between the two ends of the supporting sheet 50. One end of the flexible member 30 is fixed to one end of the support sheet 50, and the other end is fixed to the first frame 21. Parts of the flexible screen 30 cover between the two ends of associated parts of the supporting sheet 50 and are slidable relative to the associated parts of the supporting sheet 50. At this time, one side of the middle hinge 250 is configured to fit the flexible screen 30, and the first virtual axis L1 and the second virtual axis L2 are away from one side of the middle hinge 250 configured to fit the flexible screen 30 relative to the two shafts 281.

When the foldable device 22 is in the unfolded state, the first connection rod 2581 of the connection rod 2580 is fitted to the second stopping surface 25591 of the second stopper 2559. When a middle area of the foldable device 22 is subjected to an extrusion pressure, the foldable device 22 will not be compressed in a transverse direction due to the extrusion pressure, thus arching a screen of the flexible screen 30. When the foldable device 22 is in the folded state, the first connection rod 2581 of the connection rod 2580 abuts against the first stopping surface 25581 of the stopping bar 2558 and the first stopper 2595. When the middle area of the foldable device 22 is subjected to the extrusion pressure, the foldable device 22 will not be compressed in the transverse direction due to the extrusion pressure, thus arching the screen of the flexible screen 30.

Optionally, when the foldable device 22 is folded, the supporting sheet 50 can drive the connection plate 2561 to slide relative to the second frame 23, and the flexible screen can drive the first frame 21 to slide relative to the second frame 23. The supporting sheet 50 can also drive the connection plate 2561 to slide relative to the second frame 23 toward the second frame 23, and the flexible screen can drive the first frame 21 to slide towards the second frame 23 relative to the second frame 23. The bendable area 31 of the flexible member 30 can be folded as the foldable device 22 is folded. The first elastic member 2553 pushes the connection piece 2563 outward to drive the connection plate 2561 to abuts against the supporting sheet 50 to one side away from the middle hinge 250 to allow the supporting sheet 50 to be in a tight state. The second elastic member 25515 pushes the first frame 21 outward, thus tightening the flexible screen, and thereby preventing the flexible screen from being damaged form arching. When the flexible member 30 is in the unfolded state, the fastening block 25761 of each positioning member 25760 is fastened into an associated positioning opening 2758 or associated positioning opening 2778, and the first connection rod 2581 of the connection rod 2580 abuts against the second stopping surface 25592 of the second stopper 2559, thus positioning the bendable mechanism 25 to maintain the unfolded state.

As illustrated in FIG. 26 to FIG. 32, when the electronic device 100 is folded, an force is applied to at least one of the first frame 21 and the second frame 23 of the electronic device 100 to allow the first connection hinge 254 coupled to the first frame 21 and the second connection hinge 257 of the second frame 22 to be rotated and moved toward each other, thus realizing the bending of the foldable device 22 by the two folding assisting components 24 and the bending of the bending area 31 of the flexible member 30. Specifically, if the force is applied to the first frame 21, the first frame 21 drives the first connection hinge 254 to rotate along the first virtual axis L1 relative to the middle hinge 250 to one side away from the flexible member 30. The first connection hinge 254 drives an associated transmission rods 2621 of the two folding assisting assemblies 24 to rotate, and the two first guide rail rods 275 slide in the two first sliding guide grooves 2556 of the first connection hinge 254, respectively. Such that the fastening block 25761 of the positioning member 25760 on the first connection hinge 254 is separated from an associated positioning opening 2758 of the first guide rail rod 275. The two transmission rods 2621 slide in the transmission groove 25514 of the first connection hinge 254. Since the two transmission members 262 of each of the two folding assisting assemblies 24 are coupled by the linkage mechanism 28, when one of the transmission rods 2621 coupled between the first connection hinge 254 and the linkage mechanism 28 rotates, an associated one of the two shafts 281 is driven by the transmission rod 2621 coupled between the first connection hinge 254 and the linkage mechanism 28 to rotate, the associated one of the two shafts 281 drives the other of the two shafts 281 on an opposite side to the associated one of the two shafts 281 to rotate by the linkage member 282, the other of the two shafts 281 drives the other of the transmission rods 2621 coupled between the second connection hinge 257 and the linkage mechanism 28, thus allowing the second connection hinge 257 synchronously to rotate toward the first connection hinge 254. The second connection hinge 257 drives the second guide rail rod 277 to slide in the second sliding guide groove 2570, and the second guide rail rod 277 slidably abuts against an associated positioning member 25760 to slide away from the second guide rail rod 275. The elastic member 25765 is elastically deformed. Such that the fastening block 25761 of the positioning member 25760 is separated from the corresponding positioning opening 2778, and the two second guide rail rods 277 of each of the two folding assisting assemblies are also close to each other to allow the foldable device 22 to be in the folded state. The bendable area 31 of the flexible member 30 is folded as the foldable device 22 is folded until the back surface of the first frame 21 is fitted to the back surface of the second frame 23.

At this time, the foldable device 22 is folded, and the flexible member 30 is folded as the foldable device 22 is folded. Such that the middle hinge 250 is coupled to the front surface of the first connection hinge 254 and the front surface of the second connection hinge 257 to form an arch cambered surface, thus facilitating the fitting of flexible member 30.

In a folding process of the foldable device 22, the connection hinges rotate around the virtual axes relative to the middle hinge 250. Specifically, each shielding mechanism 29 is folded as the foldable device 22 is folded, that is, the plurality of the shielding units of the first shielding mechanism 290 are bent along the foldable device 22. The shielding part 2912 of the middle shielding piece 291, the shielding part 2922 of the connection shielding piece 292, and the shielding part 2932 of the fixed shielding piece 293 overlap each other, thus preventing dust and other impurities from entering into the foldable device 22 from opposite sides of the electronic device 100. The first blocking member 2951 and the second blocking member 2953 of the first blocking mechanism 290 are bent with the foldable device 22, thus preventing dust and other impurities from entering into the foldable device 22 from the back surface of the electronic device 100.

In other bending methods of the electronic device 100, a force can be only applied to the second frame 23, and the second frame 23 drives the second connection hinge 257 to rotate to one side away from the flexible member 30 around the second virtual axis L2 relative to the middle hinge 250. The second connection hinge 257 drives an associated transmission rod 2621 of the two folding assisting assemblies 24 to rotate, and the two second guide rail rods 277 are respectively slide in the two second sliding guide grooves 2570 in the second connection hinge 257, to allow the fastening block 25761 of the positioning member 25760 on the second connection hinge 257 to be separated from an associated positioning opening 2778 of the second guide rail rod 277. The two transmission rods 2621 slide in the transmission grooves 2577 in the second connection hinge 257. Since the two transmission members 262 of each of the two folding assisting assemblies 24 are coupled by the linkage mechanism 28, one of the transmission rods 2621 coupled between the second connection hinge 257 and the linkage mechanism 28 rotates, an associated one of the two shafts 281 is driven by the transmission rod 2621 coupled between the second connection hinge 257 and the linkage mechanism 28 to rotate, the associated one of the two shafts 281 drives the other of the two shafts 281 on an opposite side to the associated one of the two shafts 281 to rotate by the linkage member 282, the other of the two shafts 281 drives the other of the transmission rods 2621 coupled between the first connection hinge 254 and the linkage mechanism 28 to rotate, thus allowing the first connection hinge 254 to rotate toward the second connection hinge 257 synchronously. The first connection hinge 254 drives the first guide rail rod 275 to slide in the first sliding groove 2556. The first guide rail rod 275 slidably abuts against an associated positioning member 25760 to slide away from the first guide rail rod 275. The elastic member 25765 is elastically deformed. The fastening block 25761 of the positioning member 25760 is separated from the associated positioning member 25760. The two first guide rail rods 275 of each of the two folding assisting assemblies 24 are close to each other, to allow the foldable device 22 to be in a folded state, and the bendable area 31 of the flexible member 30 is bent with the foldable device 22 until the back surface of the first frame 21 is fitted to the back surface of the second frame 23.

In other bending methods of the electronic device 100, forces can be also applied to the first frame 21 and the second frame 23 simultaneously. The first frame 21 and the second frame 23 respectively drive the first connection hinge 254 and the second connection hinge 257 to rotate relative to one side away from the flexible member 30, and realizing the bending of the electronic device 100 by the foldable device 22.

When the electronic device 100 needs to be unfolded, the first frame 21 or the second frame 23 is pulled outward, and the first connection hinge 254 coupled to the first frame 21 and the second connection hinge 257 coupled to the second frame 23 are rotated to each other and moved away from each other. Specifically, a force is applied to at least one of the first frame 21 and the second frame 23 of the electronic device 100 to be pulled outward, such that the first connection hinge 254 coupled to the first frame 21 and the second connection hinge 257 coupled to the second frame 23 rotate to each other and move away from each other. If a force is applied to the first frame 21 to be pulled outward, the first frame 21 drives the first connection hinge 254 to rotate along the first virtual axis L1 toward one side of the flexible member 30, and the first guide rail rods 275 are respectively slidable in the two first sliding guide grooves 2556 in the first connection hinge 254, to abut against the positioning member 25760 to slide away from an associated first guide rail rod 275. The elastic member 25765 is elastically deformed until the fastening block 25761 of the positioning member 25760 is fastened to an associated positioning opening 2758. At the same time, the two transmission rods 2621 slide in the transmission groove 25514 of the first connection hinge 254. Since the two transmission members 262 of each of the two folding assisting assemblies 24 are coupled by the linkage mechanism 28, when one of the two transmission rods 2621 coupled between the first connection hinge 254 and the linkage mechanism 28 rotates, an associated one of the two shafts 281 is driven by the two transmission rod 2621 coupled between the first connection hinge 254 and the linkage mechanism 28 to rotate, the associated one of the two shafts 281 drives the other of the two shafts 281 on an opposite side to the associated one of the two shafts 281 to rotate via the linkage member 282, the other of the two shafts 281 drives the other of the two transmission rods 2621 coupled between the second connection hinge 257 and the linkage mechanism 28 to rotate, thus allowing the second connection hinge 257 synchronously to rotate away from the first connection hinge 254. The second connection hinge 257 drives the second guide rail rod 277 to slide in the second sliding guide groove 2570, the second guide rail rod 277 slidably abuts against an associated positioning member 25760 to slide away from the second guide rail rod 275, and the elastic member 25765 is elastically deformed until the fastening block 25761 of the positioning member 25760 is fastened into an associated positioning opening 2778. Such that the two second guide rail rods 277 of each of the two folding assisting assemblies 24 are also move away from each other until the foldable device 22 is in an unfolded state. The bendable area 31 of the flexible member 30 is unfolded with the foldable device 22.

In other unfolding methods of the electronic device 100, a force can be only applied to the second frame 23 to be pulled outward, and the electronic device 100 is unfolded by the foldable device 22 and the second frame 23.

In other folding methods of the electronic device 100, forces can be simultaneously applied to the first frame 21 and the second frame 23 to be pulled outward. The first frame 21 and the second frame 23 are respectively drive an associated one of the connection hinges and an associated rotating hinge to rotate relative to the middle hinge 250 toward one side of the flexible member 30, thus realizing the unfolding of the electronic device 100.

The foregoing description merely depicts some exemplary embodiments of the disclosure. It should be noted that, those skilled in the art may also make a plurality of improvements and refinements without departing from the principles of the present disclosure. The plurality of improvements and refinements should all be encompassed within the protection of the present disclosure.

What is claimed is:

1. A foldable device, comprising a bendable mechanism, a connection mechanism, and a shielding mechanism, wherein the connection mechanism is coupled to the bendable mechanism, and is slidable relative to the bendable mechanism as the bendable mechanism is folded; the shielding mechanism is arranged on an inner side of the bendable mechanism; the shielding mechanism is coupled to the connection mechanism; when the bendable mechanism is folded, the connection mechanism is capable of driving the shielding mechanism to slide relative to the bendable mechanism.

2. The foldable device of claim 1, wherein the shielding mechanism includes a virtual axis, when the bendable mechanism is folded, the shielding mechanism is slidable relative to the bendable mechanism around the virtual axis of the shielding mechanism.

3. The foldable device of claim 2, wherein the virtual axis of the shielding mechanism is located in the shielding mechanism.

4. The foldable device of claim 1, wherein the bendable mechanism comprises a middle hinge, which is located in a middle of the bendable mechanism, and connection hinges rotatably coupled to two opposite sides of the middle hinge; the shielding mechanism covers at least the middle hinge.

5. The foldable device of claim 4, wherein the connection mechanism is rotatably coupled to the middle hinge and slidable relative to the connection hinges.

6. The foldable device of claim 5, wherein the connection mechanism includes a virtual axis, the connection mechanism is slidable relative to the middle hinge around the virtual axis of the connection mechanism.

7. The foldable device of claim 6, wherein the virtual axis of the connection mechanism is located in the shielding mechanism.

8. The foldable device of claim 6, wherein the virtual axis of the connection mechanism is close to the middle hinge and away from the connection hinges.

9. The foldable device of claim 4, wherein the foldable device further comprises a linkage mechanism coupled to the middle hinge; when one of the connection hinges located on one side of the middle hinge rotates, the linkage mechanism drives an associated one of the connection hinges located on the other side of the middle hinge to rotate.

10. The foldable device of claim 9, wherein the middle hinge comprises an intermediate hinge, a first rotating hinge located on a first side of the intermediate hinge, and a second rotating hinge located on a second side of the intermediate hinge.

11. The foldable device of claim 10, wherein the connection mechanism comprises at least one guide rail block coupled to the middle hinge and at least one guide rail rod rotatably coupled to the at least one guide rail block.

12. The foldable device of claim 11, wherein the at least one guide rail block comprises a first guide rail block and a second guide rail block; the at least one guide rail rod comprises a first guide rail rod and a second guide rail rod; the virtual axis of the connection mechanism comprises a first virtual axis and a second virtual axis; the first guide rail block comprises a first guide rail curve surface, of which an axis is taken as the first virtual axis; a side of the first guide rail rod facing to the intermediate hinge is provided with a first guide rail matching surface, which is fitted with the first guide rail curve surface; the first guide rail matching surface rotates along a track of the first guide rail curve surface; the second guide rail block comprises a second guide rail curve surface, of which an axis is taken as the second virtual axis; a side of the second guide rail rod facing to the intermediate hinge is provided with a second guide rail matching surface, which is fitted with the second guide rail curve surface; the second guide rail matching surface rotates along a track of the second guide rail curve surface.

13. The foldable device of claim 12, wherein the intermediate hinge comprises a first part and a second part; the shielding mechanism comprises a first shielding member and a second shielding member; the first shielding member covers at least the first part of the intermediate hinge and the first rotating hinge; the second shielding member covers at least the second part of the intermediate hinge and the second rotating hinge.

14. The foldable device of claim 13, wherein the first virtual axis is located in the first shielding member; the second virtual axis is located in the second shielding member.

15. The foldable device of claim 13, wherein the first shielding member is fixedly coupled to the first guide rail rod; the second shielding member is fixedly coupled to the second guide rail rod.

16. The foldable device of claim 4, wherein a movement of each of the connection hinges relative to the middle hinge includes a rotating movement of an associated one of the connection hinges relative to the middle hinge and a sliding movement of the associated one of the connection hinges relative to the middle hinge; the associated one of the connection hinges slides relative to the middle hinge while rotating relative to the middle hinge.

17. The foldable device of claim 4, wherein the connection hinges are rotatable relative to the middle hinge around a virtual axis of the shielding mechanism; when the connection hinges are movable relative to the middle hinge, the connection mechanism is slidable relative to the connection hinges.

18. The foldable device of claim 4, wherein the foldable device further comprises a transmission mechanism coupled to the middle hinge and the connection hinges; when the bendable mechanism is folded, the transmission mechanism is slidable relative to the connection hinges; a slide vector of the transmission mechanism relative to an associated one of the connection hinges includes a first slide component and a second slide component; the first slide component faces away from or toward the middle hinge, and the second slide component is perpendicular to the first slide component.

19. The foldable device of claim 18, wherein the transmission mechanism comprises two transmission members rotatably coupled to each other; one end of an associated one of the two transmission members of the transmission mechanism is rotatably coupled to the middle hinge by a shaft; the other end of the associated one of the two transmission members of the transmission mechanism is slidably coupled to an associated one of the connection hinges.

20. An electronic device, comprises a flexible member, a housing, and a foldable device; the housing comprises a first frame and a second frame; the foldable device is arranged between the first frame and the second frame; the flexible member is arranged on the housing and the foldable device; the flexible member is folded or unfolded together with the foldable device; the foldable device comprises a bendable mechanism, a connection mechanism, and a shielding mechanism; the connection mechanism is coupled to the bendable mechanism, and is slidable relative to the bendable mechanism as the bendable mechanism is folded; the shielding mechanism is arranged on an inner side of the bendable mechanism; the shielding mechanism is coupled to the connection mechanism; when the bendable mechanism is folded, the connection mechanism is capable of driving the shielding mechanism to slide relative to the bendable mechanism.
